(19) United States
(12) Patent Application Publication
(10) Pub. No.: US 2024/0292677 A1
(43) Pub. Date: Aug. 29, 2024

(54) DISPLAY DEVICE

(71) Applicant: Samsung Display Co., Ltd., Yongin-si (KR)

(72) Inventors: PILSUK LEE, Yongin-si (KR); YOOMIN KO, Yongin-si (KR); SUNHO KIM, Yongin-si (KR); Hyewon KIM, Yongin-si (KR); JUCHAN PARK, Yongin-si (KR); CHUNG SOCK CHOI, Yongin-si (KR); SUNGJIN HONG, Yongin-si (KR)

(21) Appl. No.: 18/584,655

(22) Filed: Feb. 22, 2024

(30) Foreign Application Priority Data
Feb. 24, 2023 (KR) 10-2023-0025206

(51) Int. Cl. H10K 59/124; H10K 59/121; H10K 59/122; H10K 59/131; H10K 85/30

(52) U.S. Cl. CPC H10K 59/124; H10K 59/1213; H10K 59/131; H10K 85/324; H10K 59/122

(57) ABSTRACT

A display device includes a display element layer including a plurality of light emitting portions, and a partition structure for separating the light emitting portions, and a circuit layer including a plurality of transistors, a first insulation layer on the transistors and having a plurality of first holes not overlapping the light emitting portions, a second insulation layer on the first insulation layer and having a plurality of second holes not overlapping the first holes, and a plurality of connection wiring portions for electrically connecting the light emitting portions and the transistors, and which includes extension wiring respectively connecting the light emitting portions and the transistors.

### CROSS-REFERENCE TO RELATED APPLICATIONS

The present application claims priority to and the benefit of Korean Patent Application No. 10-2023-0025206, filed on Feb. 24, 2023, the entire content of which is incorporated herein by reference.

### BACKGROUND

### 1. Field

Aspects of some embodiments of the present disclosure relate to a display device.

### 2. Description of the Related Art

Multimedia electronic devices such as televisions, mobile phones, tablets, computers, navigation system units, and game consoles include a display device for displaying images.

The display device includes a light emitting element and a circuit for driving the light emitting element. Light emitting elements included in the display device emit light and generate images in response to a voltage applied from the circuit. In order to improve the reliability of the display device, research is underway on the connection of the light emitting element and the circuit. In addition, in order to prevent or reduce degradation of the display quality of the display device, the arrangement of a circuit unit and wires may be considered.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device with improved external light reflection.

Aspects of some embodiments of the present disclosure include a display device having relatively excellent display quality due to relatively improved external light reflection.

According to some embodiments of the present disclosure, a display device includes: a display element layer including a plurality of light emitting portions, and a partition structure for separating the light emitting portions, and a circuit layer including a plurality of transistors, a first insulation layer on the transistors and having a plurality of first holes not overlapping the light emitting portions, a second insulation layer on the first insulation layer and having a plurality of second holes not overlapping the first holes, and a plurality of connection wiring portions for electrically connecting the light emitting portions and the transistors, wherein each of the light emitting portions includes a light emitting element including a first electrode, a second electrode facing the first electrode, and a light emitting layer between the first electrode and the second electrode, and each of the connection wiring portions includes a driving connection part electrically connected in correspondence to each of the transistors, and in each of the first holes, an emission connection part electrically connected to the light emitting element, and having one side exposed in each of the second holes, and an extension wiring for connecting the emission connection part and the driving connection part.

According to some embodiments, the driving connection part in each of the first holes may not overlap the light emitting portions.

According to some embodiments, the first holes may not overlap the light emitting layer.

According to some embodiments, the first electrode may be on the second insulation layer, and an upper surface of the first electrode may be exposed in a light emitting opening defined in the partition structure, wherein the first holes may not overlap the first electrode exposed in the light emitting opening.

According to some embodiments, the display device may be separated into a display region in which the light emitting portions are located and a peripheral region on an outer periphery of the display device, wherein the connection line portion connected to the light emitting portions adjacent to the peripheral region may be longer than the connection line portion connected to the light emitting portions in the center of the display region.

According to some embodiments, the light emitting portions may include a first light emitting portion, a second light emitting portion, and a third light emitting portion, which emit light of different wavelength regions from each other, wherein the first light emitting portion to the third light emitting portion may constitute one light emitting unit, wherein a plurality of the light emitting units each including the first to third light emitting portions may be arranged in a first direction or in a second direction crossing the first direction.

According to some embodiments, the circuit layer may include a first pixel driver electrically connected to the first light emitting portion, a second pixel driver electrically connected to the second light emitting portion, and a third pixel driver electrically connected to the third light emitting portion, wherein the first pixel driver to the third pixel driver may constitute one driving unit, wherein a plurality of the driving units each including the first pixel driver to the third pixel driver may be arranged in the first direction or in the second direction.

According to some embodiments, a width of each of the driving units in the first direction may be smaller than a width of each of the light emitting units in the first direction.

According to some embodiments, the extension wiring may include a transparent conductive metal material.

According to some embodiments, the driving connection part and the emission connection part may each include a first layer including titanium, a second layer on an upper side of the first layer and including aluminum, and a third layer on an upper side of the second layer and including titanium, wherein all of the layers are sequentially stacked.

According to some embodiments of the present disclosure, a display device includes a base layer, a plurality of transistors on the base layer, an interlayer insulation layer on the transistors, a first insulation layer on the interlayer insulation layer, and having a plurality of first holes, a second insulation layer on the first insulation layer, and having a plurality of second holes not overlapping the first holes, a display element layer on the second insulation layer, and including a pixel definition layer having light emitting openings and a plurality of light emitting elements in each of the light emitting openings, and a plurality of connection wiring portions including a driving connection part in each of the first holes and electrically connected to the transistors, an emission connection part exposed from each of the second holes and electrically connected to the light emitting elements, and an extension wiring for connecting the driving connection part and the emission connection part, wherein the first holes do not overlap the light emitting openings.

According to some embodiments, each of the light emitting elements may include a first electrode, a second electrode facing the first electrode, and a light emitting layer between the first electrode and the second electrode, wherein the second electrode may include one end separated from a portion overlapping the second hole.

According to some embodiments, the separated one end of the second electrode may be electrically connected to the emission connection part in each of the second holes.

According to some embodiments, a contact hole may be defined in the interlayer insulation layer, and an electrode pattern in the contact hole may be further included, wherein each of the transistors may be connected to the driving connection part through the electrode pattern.

According to some embodiments of the present disclosure, a display device is separated into a display region including a first region, a second region, and a third region, which are arranged in a first direction, and a peripheral region around the display region, and the display device includes a plurality of light emitting units in the first region to the third region, and each including a plurality of light emitting portions, a plurality of driving units in the first region and the second region, and including a plurality of pixel drivers electrically connected to each of the light emitting portions, and a plurality of connection wiring portions including an emission connection part connected to each of the light emitting portions, a driving connection part connected to each of the pixel drivers, and an extension wiring for connecting a corresponding emission connection part and the driving connection part, wherein the driving connection part does not overlap the light emitting portions.

According to some embodiments, the driving connection part electrically connected to the light emitting portions in the first region may be in the first region, and the driving connection part electrically connected to the light emitting portions in the third region may be in the second region.

According to some embodiments, the extension wiring for connecting the emission connection part connected to the light emitting portions in the third region and the driving connection part electrically connected to the emission connection part may be longer than the extension wiring for connecting the emission connection part connected to the light emitting portions in the first region and the driving connection part electrically connected to the emission connection part.

According to some embodiments, an extension wiring included in each of the connection wiring portions connected to the light emitting portions in the third region may overlap a plurality of light emitting portions.

According to some embodiments, a width of each of the light emitting units in the first direction may be smaller than a width of each of the driving units in the first direction.

According to some embodiments, the pixel drivers may each include a transistor and an electrode pattern on the transistor and connected to the transistor, wherein the transistor may include a semiconductor pattern including a source region, a drain region, and a channel region between the source region and the drain region, and a gate electrode on an upper side of the semiconductor pattern, wherein the driving connection part may be electrically connected to the drain region through the electrode pattern.

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain principles of the present disclosure. In the drawings:

FIG. 1 is a block diagram of a display device according to some embodiments of the present disclosure;

FIG. 2A and FIG. 2B are each an equivalent circuit diagram of a pixel according to some embodiments of the present disclosure;

FIG. 3A and FIG. 3B are each a plan view of a display panel according to some embodiments of the present disclosure;

FIG. 4 is a plan view of an enlarged partial region of the display panel illustrated in FIG. 3A according to some embodiments of the present disclosure;

FIG. 5 is an exploded perspective view showing an enlarged portion of a display panel according to some embodiments of the present disclosure;

FIG. 6A is a plan view of one light emitting unit in the display panel illustrated in FIG. 5 according to some embodiments of the present disclosure;

FIG. 6B is a plan view of one driving unit in the display panel illustrated in FIG. 5 according to some embodiments of the present disclosure;

FIG. 7A is a plan view showing an enlarged partial region of a display panel according to some embodiments of the present disclosure;

FIG. 7B is an enlarged plan view of light emitting units in one row illustrated in FIG. 7A according to some embodiments of the present disclosure;

FIG. 7C is a plan view showing an enlarged partial region of a display panel according to some embodiments of the present disclosure;

FIG. 8 is a cross-sectional view showing a portion corresponding to the line I-I′ of FIG. 7B according to some embodiments of the present disclosure;

FIG. 9A is a cross-sectional view showing an enlarged view of the region AA′ of FIG. 8 according to some embodiments of the present disclosure;

FIG. 9B is a cross-sectional view showing an enlarged view of the region BB′ of FIG. 8 according to some embodiments of the present disclosure;

FIG. 9C is a cross-sectional view showing an enlarged view of the region CC′ of FIG. 8 according to some embodiments of the present disclosure;

FIG. 10 is a plan view showing an enlarged partial region of a display panel according to some embodiments of the present disclosure;

FIG. 11 is a cross-sectional view showing a portion corresponding to the line II-II′ of FIG. 10 according to some embodiments of the present disclosure; and

FIG. 12 is a plan view schematically showing a connection relationship between some light emitting units and some driving units according to some embodiments of the present disclosure.

### DETAILED DESCRIPTION

Aspects of some embodiments of the present disclosure may be modified in many alternate forms, and thus specific embodiments will be illustrated in the drawings and described in more detail. It should be understood, however, that it is not intended to limit the scope of embodiments according to the present disclosure to the particular forms disclosed, but rather, is intended to cover all modifications, equivalents, and alternatives falling within the spirit and scope of embodiments according to the present disclosure.

In the present disclosure, when an element (or a region, a layer, a portion, etc.) is referred to as being “on,” “connected to,” or “coupled to” another element, it means that the element may be directly located on/connected to/coupled to the other element, or that a third element may be located therebetween.

Meanwhile, in the present disclosure, being “directly located” may mean that there is no layer, film, region, plate, or the like added between a portion of a layer, a film, a region, a plate, or the like and other portions. For example, being “directly located” may mean being located without additional members such as an adhesive member between two layers or two members.

Like reference numerals refer to like elements. Also, in the drawings, the thickness, the ratio, and the dimensions of elements are exaggerated for an effective description of technical contents. The term “and/or” includes any and all combinations of one or more of which associated elements may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of components shown in the drawings. The terms are used as a relative concept and are described with reference to the direction indicated in the drawings. In the present disclosure, being “located on” may not only include the case of being located in an upper portion of any one member but also the case of being located in a lower portion thereof.

Unless otherwise defined, all terms (including technical and scientific terms) used herein have the same meaning as commonly understood by one of ordinary skill in the art to which embodiments according to the present disclosure pertain. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Hereinafter, a display device according to some embodiments of the present disclosure will be described in more detail with reference to the accompanying drawings.

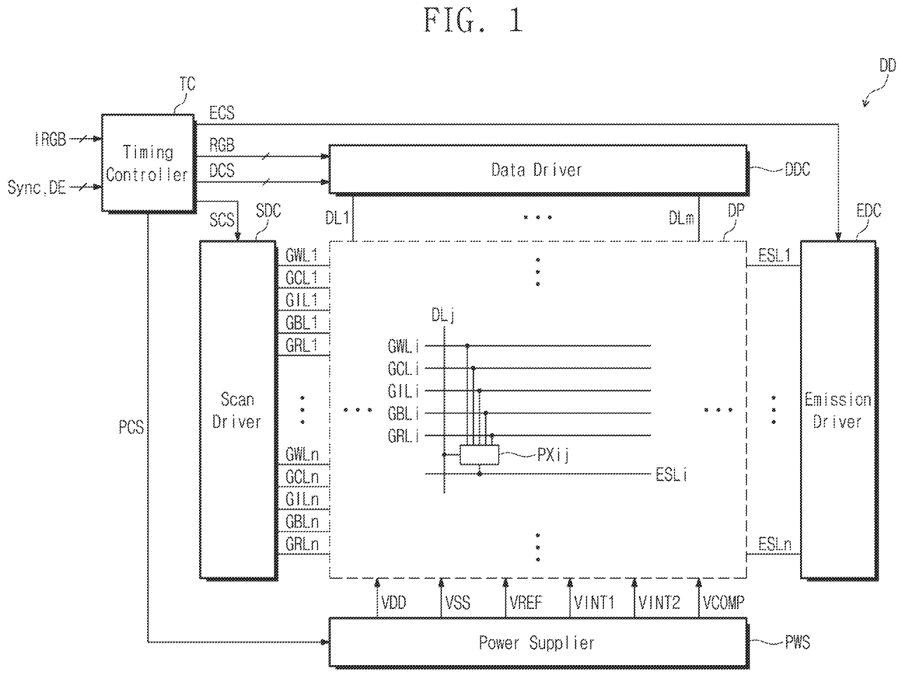

FIG. 1 is a block diagram of a display device DD according to some embodiments of the present disclosure. Referring to FIG. 1, a display device DD may include a display panel DP, panel drivers SDC, EDC, and DDC, a power supplier PWS, and a timing controller TC. According to some embodiments, the display panel DP is described as being a light emitting type display panel. The light emitting type display panel DP may include an organic light emitting display panel, an inorganic light emitting display panel, or a quantum dot light emitting display panel. According to some embodiments to be described in more detail later, an organic light emitting display panel will be described in more detail as an example. The panel drivers may include a scan driver SDC, an emission driver EDC, and a data driver DDC.

The display panel DP may include scan lines GWL1 to GWLn, GCL1 to GCLn, GIL1 to GILn, GBL1 to GBLn, and GRL1 to GRLn, emission lines ESL1 to ESLn, and data lines DL1 to DLm. The display panel DP may include a plurality of pixels connected to the scan lines GWL1 to GWLn, GCL1 to GCLn, GIL1 to GILn, GBL1 to GBLn, and GRL1 to GRLn, emission lines ESL1 to ESLn, and data lines DL1 to DLm. (wherein, m and n are integers greater than 1).

For example, a pixel PXij (wherein i and j are integers greater than 1) positioned at an i-th horizontal line (or, an i-th pixel row) and a j-th vertical line (or, a j-th pixel column) may be connected to an i-th first scan line GWLi (or a write scan line), an i-th second scan line GCLi (or a compensation scan line), an i-th third scan line GILi (or a first initialization scan line), an i-th fourth scan line GBLi (or a second initialization scan line), an i-th fifth scan line GRLi (or a reset scan line), a j-th data line DLj, and an i-th emission line ESLi.

The pixel PXij may include a plurality of light emitting elements, a plurality of transistors, and a plurality of capacitors. The pixel PXij may be supplied with a first power voltage VDD, a second power voltage VSS, a third power voltage VREF (or a reference voltage), a fourth power voltage VINT1 (or a first initialization voltage), a fifth power voltage VINT2 (or a second initialization voltage), and a sixth power voltage VCOMP (or a compensation voltage) through the power supplier PWS.

The voltage values of the first power voltage VDD and the second power voltage VSS are set such that a current flows through a light emitting element to emit light. For example, the first power voltage VDD may be set to a voltage higher than the second power voltage VSS.

The third power voltage VREF may be a voltage for initializing a gate of a driving transistor included in the pixel PXij. The third power voltage VREF may be used to implement a gray scale (e.g., a set or predetermined gray scale) by using a voltage difference with a data signal. To this end, the third power voltage VREF may be set to a voltage (e.g., a set or predetermined voltage) within a voltage range of the data signal.

The fourth power voltage VINT1 may be a voltage for initializing a capacitor included in the pixel PXij. The fourth power voltage VINT1 may be set to a voltage lower than the third power voltage VREF. For example, the fourth power voltage VINT1 may be set to a voltage lower than a difference between the third power supply voltage VREF and a threshold voltage of the driving transistor. However, an embodiments according to the present disclosure are not limited thereto.

The fifth power voltage VINT2 may be a voltage for initializing a cathode of a light emitting element included in the pixel PXij. The fifth power voltage VINT2 may be set to a voltage lower than the first power voltage VDD or the fourth power voltage VINT1 or may be set to a voltage similar to or the same as the third power voltage VREF, but the embodiments of the present disclosure are not limited thereto, and the fifth power voltage VINT2 may be set to a voltage similar to or the same as the first power voltage VDD.

The sixth power voltage VCOMP may supply a current (e.g., a set or predetermined current) to the driving transistor when the threshold voltage of the driving transistor is compensated.

Meanwhile, FIG. 1 illustrates that the first to sixth power voltages VDD, VSS, VREF, VINT1, VINT2, and VCOMP are all supplied from the power supplier PWS, but the embodiments of the present disclosure are not limited thereto. For example, the first power voltage VDD and the second power voltage VSS are all supplied regardless of a structure of the pixel PXij, and at least one voltage of the third power voltage VREF, the fourth power voltage VINT1, the fifth power voltage VINT2, or the sixth power voltage VCOMP may not be supplied in correspondence to the structure of the pixel PXij.

According to some embodiments, signal lines connected to the pixel PXij may be variously set in correspondence to a circuit structure of the pixel PXij.

The scan driver SDC may receive a first control signal SCS from the timing controller TC, and may supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn based on the first control signal SCS.

The scan signal may be set to a voltage at which transistors which are supplied with the scan signal may be turned on. For example, a scan signal supplied to a P-type transistor may be set to a logic low level, and a scan signal supplied to an N-type transistor may be set to a logic high level. Hereinafter, the meaning of “a scan signal is supplied” may be understood as that a scan signal is supplied at a logic level which turns on a transistor controlled by the scan signal.

In FIG. 1, for convenience of description, the scan driver SDC is illustrated as having a single configuration, but the embodiments of the present disclosure are not limited thereto. According to some embodiments, a plurality of scan drivers may be included to supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The emission driver EDC may supply an emission signal to the emission lines ESL1 to ESLn based on a second control signal ECS. For example, the emission signal may be sequentially supplied to the emission lines ESL1 to ESLn.

Transistors connected to the emission lines ESL1 to ESLn of the present disclosure may be configured as N-type transistors. At this time, the emission signal supplied to the emission lines ESL1 to ESLn may be set to a gate-off voltage. Transistors receiving an emission signal may be turned off when the emission signal is supplied, and may be set to the state of being turned-on otherwise.

The second control signal ECS includes an emission start signal and clock signals, and the emission driver EDC may be implemented as a shift register which sequentially shifts the emission start signal in a pulse form using the clock signals so as to sequentially generate and output an emission signal in a pulse form.

The data driver DDC may receive a third control signal DCS and image data RGB from the timing controller TC. The data driver DDC may convert the image data RGB in a digital form into an analog data signal (i.e., a data signal). The data driver DDC may supply a data signal to the data lines DL1 to DLm in correspondence to the third control signal DCS.

The third control signal DCS may include a data enable signal, a horizontal start signal, a data clock signal, and the like, which indicate the output of a valid data signal. For example, the data driver DDC may include a shift register configured to shift a horizontal start signal in synchronization with a data clock signal to generate a sampling signal, a latch configured to latch the image data RGB in response to the sampling signal, a digital-to-analog converter (or, a decoder) configured to convert the latched image data (e.g., data in a digital form) into data signals in an analog form, and buffers (or, amplifiers) configured to output the data signals to the data lines DL1 to DLm.

The power supplier PWS may supply the first power voltage VDD, the second power voltage VSS, and the third power voltage VREF for driving the pixel PXij to the display panel DP. In addition, the power supplier PWS may supply at least one voltage of the fourth power voltage VINT1, the fifth power voltage VINT2, or the sixth power voltage VCOMP to the display panel DP.

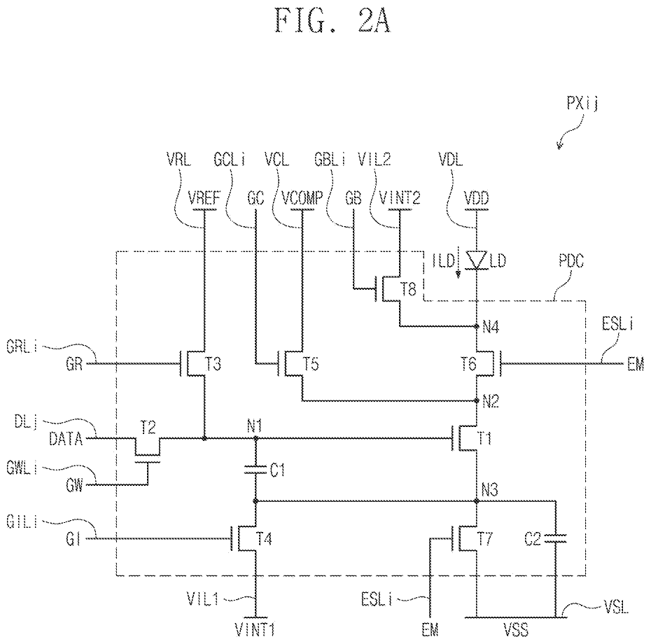

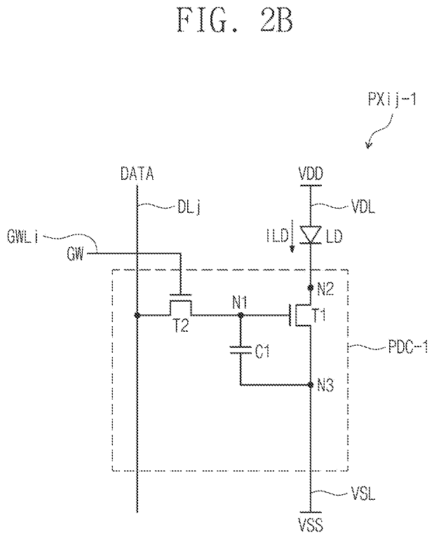

As an example, the power supplier PWS may respectively supply the first power voltage VDD, the second power voltage VSS, the third power voltage VREF, the fourth power voltage VINT1, the fifth power voltage VINT2, and the sixth power voltage VCOMP to the display panel DP via a first power line VDL (see FIG. 2A), a second power line VSL (see FIG. 2A), a third power line VRL (or a reference voltage line, see FIG. 2A), a fourth power line VIL1 (or a first initialization voltage line, see FIG. 2A), a fifth power line VIL2 (or a second initialization voltage line, see FIG. 2A), and a sixth power line VCL (or a compensation voltage line, see FIG. 2A), which are not illustrated.

The power supplier PWS may be implemented as a power management integrated circuit, but is not limited thereto.

The timing controller TC may generate the first control signal SCS, the second control signal ECS, the third control signal DCS, and a fourth control signal PCS based on input image data IRGB, a synchronization signal Sync (e.g., a vertical synchronization signal, a horizontal synchronization signal, etc.), a data enable signal DE, a clock signal, etc. The first control signal SCS may be supplied to the scan driver SDC, the second control signal ECS may be supplied to the emission driver EDC, the third control signal DCS may be supplied to the data driver DDC, and the fourth control signal PCS may be supplied to the power supplier PWS. The timing controller TC may generate the image data RGB (or, frame data) by rearranging the input image data IRGB in correspondence to an arrangement of the pixel PXij in the display panel DP.

Meanwhile, the scan driver SDC, the emission driver EDC, the data driver DDC, the power supplier PWS, and/or the timing controller TC may be directly provided on the display panel DP, or may be provided in the form of a separate driving chip and be connected to the display panel DP. In addition, at least two among the scan driver SDC, the emission driver EDC, the data driver DDC, the power supplier PWS, and the timing controller TC may be provided as one driving chip. For example, the data driver DDC and the timing controller TC may be provided as one driving chip.

In the above, the display device DD according to some embodiments of the present disclosure has been described with reference to FIG. 1, but the display device according to embodiments of the present disclosure are not limited thereto. Signal lines may be further added or omitted depending on the configuration of a pixel. In addition, the connection relationship between one pixel and signal lines may be changed. When any one of the signal lines is omitted, another signal line may replace the omitted signal line.

FIG. 2A and FIG. 2B are equivalent circuit diagrams of a pixel according to some embodiments of the present disclosure. FIG. 2A and FIG. 2B illustrate equivalent circuit diagrams of pixels PXij and PXij−1 connected to the i-th first scan line GWLi (hereinafter, a first scan line) and connected to the j-th data line DLj (hereinafter, a data line).

As illustrated in FIG. 2A, the pixel PXij includes a light emitting element LD and a pixel driver PDC. The light emitting element LD is connected to the first power line VDL and to the pixel driver PDC.

The pixel driver PDC may be connected to the plurality of scan lines GWLi, GCLi, GILi, GBLi, and GRLi, the data line DLj, the emission line ESLi, and the plurality of power voltage lines VDL, VSL, VIL1, VIL2, VRL, and VCL. The pixel driver PDC includes first to eighth transistors T1, T2, T3, T4, T5, T6, T7, and T8, a first capacitor C1, and a second capacitor C2. Hereinafter, a case in which each of the first to eighth transistors T1, T2, T3, T4, T5, T6, T7, and T8 is an N-type transistor will be described as an example. However, the embodiments of the present disclosure are not limited thereto, and some of the first to eighth transistors T1 to T8 may be N-type transistors and the others may be P-type transistors, or each of the first to eighth transistors T1 to T8 may be a P-type transistor, but the embodiments of the present disclosure are not limited to any one embodiment.

A gate of the first transistor T1 may be connected to a first node N1. A first electrode of the first transistor T1 may be connected to a second node N2, and a second electrode thereof may be connected to a third node N3. The first transistor T1 may be a driving transistor. The first transistor T1 may control a driving current ILD flowing from the first power line VDL to the second power line VSL via the light emitting element LD in correspondence to a voltage of the first node N1. At this time, the first power voltage VDD may be set to a voltage having a potential higher than that of the second power voltage VSS.

In the present disclosure, “being electrically connected between a transistor and a signal line or between a transistor and a transistor” means that “a source, a drain, and a gate of a transistor have a shape of a single body with a signal line, or are connected through a connection electrode.”

The second transistor T2 may include a gate connected to the write scan line GWLi, a first electrode connected to the data line DLj, and a second electrode connected to the first node N1. The second transistor T2 may supply a data signal DATA to the first node N1 in response to a write scan signal GW transmitted through the write scan line GWLi. The second transistor T2 may be turned on when the write scan signal GW is supplied to the write scan line GWLi and electrically connect the data line DLj and the first node N1.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. According to some embodiments, a gate of the third transistor T3 may receive a reset scan signal GR through the i-th fifth scan line GRLi (hereinafter, a fifth scan line). The third transistor T3 may be turned on when the reset scan signal GR is supplied to the reset scan line GRLi and provide the reference voltage VREF to the first node N1.

The fourth transistor T4 may be connected between the third node N3 and the first initialization voltage line VIL1. A first electrode of the fourth transistor T4 may be connected to the third node N3, and a second electrode of the fourth transistor T4 may be connected to the first initialization voltage line VIL1 which provides the first initialization voltage VINT1. The fourth transistor T4 may be referred to as a first initialization transistor. A gate of the fourth transistor T4 may receive a first initialization scan signal GI through the i-th third scan line GILi (hereinafter, a third scan line). The fourth transistor T4 may be turned on when the first initialization scan signal GI is supplied to the first initialization scan line GILi and supply the first initialization voltage VINT1 to the third node N3.

The fifth transistor T5 may be connected between the compensation power line VCL and the second node N2. A first electrode of the fifth transistor T5 may receive the compensation voltage VCOMP through the compensation voltage line VCL, and a second electrode of the fifth transistor T5 may be connected to the second node N2 and be electrically connected to the first electrode of the first transistor T1. A gate of the fifth transistor T5 may receive a compensation scan signal GC through the i-th second scan line GCLi (hereinafter, a second scan line). The fifth transistor T5 may be turned on when the compensation scan signal GC is supplied to the compensation scan line GCLi and provide the compensation voltage VCOMP to the second node N2, and during a compensation period, a threshold voltage of the first transistor T1 may be compensated.

The sixth transistor T6 may be connected between the first transistor T1 and the light emitting element LD. For example, a gate of the sixth transistor T6 may receive an emission signal EM through the i-th emission line ESLi (hereinafter, an emission line). A first electrode of the sixth transistor T6 may be connected to a cathode of the light emitting element LD through a fourth node N4, and a second electrode of the sixth transistor T6 may be connected to the first electrode of the first transistor T1 through the second node N2. The sixth transistor T6 may be referred to as a first emission control transistor. The sixth transistor T6 may be turned on when the emission signal EM is supplied to the emission line ESLi, and electrically connect the light emitting element LD and the first transistor T1.

The seventh transistor T7 may be connected between the second power line VSL and the third node N3. A first electrode of the seventh transistor T7 may be connected to the second electrode of the first transistor T1 through the third node N3, and a second electrode of the seventh transistor T7 may receive the second power voltage VSS through the second power line VSL. A gate of the seventh transistor T7 may be electrically connected to the emission line ESLi. The seventh transistor T7 may be referred to as a second emission control transistor. The seventh transistor T7 may be turned on when the emission signal EM is supplied to the emission line ESLi, and electrically connect the second electrode of the first transistor T1 and the second power line VSL.

Meanwhile, according to some embodiments, the sixth transistor T6 and the seventh transistor T7 are illustrated as being connected to the same emission line ESLi and turned on through the same emission signal EM, but this is illustrated as an example, and the sixth transistor T6 and the seventh transistor T7 may be independently turned on by different signals distinguished from each other. In addition, in the pixel driver PDC according to some embodiments of the present disclosure, any one of the sixth transistor T6 and the seventh transistor T7 may be omitted.

The eighth transistor T8 may be connected between the second initialization voltage line VIL2 and the fourth node N4. That is, the eighth transistor T8 may include a gate connected to the i-th fourth scan line GBLi (hereinafter, a fourth scan line), a first electrode connected to the second initialization voltage line VIL2, and a second electrode connected to the fourth node N4. The eighth transistor T8 may be referred to as a second initialization transistor. The eighth transistor T8 may supply the second initialization voltage VINT2 to the fourth node N4 corresponding to the cathode of the light emitting element LD in response to a second initialization scan signal GB transmitted through the second initialization scan line GBLi. The cathode of the light emitting element LD may be initialized by the second initialization voltage VINT2.

Meanwhile, according to some embodiments, some of the second to eighth transistors T2, T3, T4, T5, T6, T7, and T8 may be simultaneously turned on through the same scan signal. For example, the eighth transistor T8 and the fifth transistor T5 may be simultaneously turned on through the same scan signal. For example, the eighth transistor T8 and the fifth transistor T5 may be operated by the same compensation scan signal GC. The eighth transistor T8 and the fifth transistor T5 may be simultaneously turned on/off by the same compensation scan signal GC. In this case, the compensation scan line GCLi and the second initialization scan line GBLi may substantially be provided as a single scan line. Accordingly, initializing the cathode of the light emitting element LD and compensating the threshold voltage of the first transistor T1 may be performed at the same timing. However, this is merely illustrative, and the embodiments of the present disclosure are not limited thereto.

In addition, according to some embodiments of the present disclosure, the initialization of the cathode of the light emitting element LD and the compensation of the threshold voltage of the first transistor T1 may be achieved with the application of the same power voltage. For example, the compensation voltage line VCL and the second initialization voltage line VIL2 may substantially be provided as a single power voltage line. In this case, because the initialization operation of a cathode and the compensation operation of a driving transistor may be performed with one power voltage, the design of a driver may be relatively simplified. However, this is merely illustrative, and the embodiments of the present disclosure are not limited thereto.

The first capacitor C1 may be located between the first node N1 and the third node N3. The first capacitor C1 may store a difference voltage between the first node N1 and the third node N3. The first capacitor C1 may be referred to as a storage capacitor.

The second capacitor C2 may be located between the third node N3 and the second power line VSL. That is, one electrode of the second capacitor C2 may be connected to the second power line VSL which is supplied with the second power voltage VSS, and the other electrode of the second capacitor C2 may be connected to the third node N3. The second capacitor C2 may be store a charge corresponding to a voltage difference between the second power voltage VSS and the second node N2.

The second capacitor C2 may be referred to as a hold capacitor. The second capacitor C2 may have a higher storage capacity than the first capacitor C1. Accordingly, the second capacitor C2 may minimize a voltage change of the third node N3 in correspondence to a voltage change of the first node N1.

According to some embodiments, the light emitting element LD may be connected to the pixel driver PDC through the fourth node N4. The light emitting element LD may include a first electrode (an anode) connected to the first power line VDL and a second electrode (a cathode) opposing the anode. According to some embodiments, the light emitting element LD may be connected to the pixel driver PDC through the cathode. That is, in the pixel PXij according to some embodiments of the present disclosure, a connection node to which the light emitting element LD and the pixel driver PDC are connected may be the fourth node N4, and the fourth node N4 may correspond to a connection node between the first electrode of the sixth transistor T6 and the cathode of the light emitting element LD. Accordingly, the potential of the fourth node N4 may substantially correspond to the potential of the cathode of the light emitting element LD.

For example, the anode of the light emitting element LD may be connected to the first power line VDL and be applied with the first power voltage VDD, which is a constant voltage, and the cathode thereof may be connected to the first transistor T1 though the sixth transistor T6. That is, in the present embodiments in which the first to eighth transistors T1 to T8 are N-type transistors, the potential of the third node N3 corresponding to a source of the first transistor T1, which is a driving transistor, may not be directly affected by the characteristics of the light emitting element LD. Therefore, even if the light emitting element LD is deteriorated, the influence on transistors constituting the pixel driver PDC, particularly a gate-source voltage Vgs of a driving transistor, may be relatively reduced. That is, because an amount of change in driving current due to the deterioration of the light emitting element LD may be reduced, an afterimage defect of a display panel due to an increase in usage time may be reduced and the lifespan thereof may be improved.

Alternatively, as illustrated in FIG. 2B, the pixel PXij−1 may include a pixel driver PDC-1 including two transistors T1 and T2 and one capacitor C1. The pixel driver PDC-1 may be connected to a light emitting element LD, a write scan line GWLi, a data line DLj, and a second power line VSL. The pixel driver PDC-1 illustrated in FIG. 2B may correspond to the pixel driver PDC illustrated in FIG. 2A from which the third to eighth transistors T3 to T8 and the second capacitor C2 are omitted.

Each of the first and second transistors T1 and T2 may be an N-type transistor or a P-type transistor. According to some embodiments, each of the first and second transistors T1 and T2 is described as an N-type transistor for ease of description.

The first transistor T1 may include a gate connected to a first node N1, a first electrode connected to a second node N2, and a second electrode connected to a third node N3. The second node N2 may be a node connected to the side of a first power line VDL, and the third node N3 may be a node connected to the side of a second power line VSL. The first transistor T1 is connected to the light emitting element LD through the second node N2 and is connected to the second power line VSL through the third node N3. The first transistor T1 may be a driving transistor.

The second transistor T2 may include a gate for receiving a write scan signal GW through the write scan line GWLi, a first electrode connected to the data line DLj, and a second electrode connected to the first node N1. The second transistor T2 may supply a data signal DATA to the first node N1 in response to the write scan signal GW transmitted through the write scan line GWLi.

The capacitor C1 may include an electrode connected to the first node N1 and an electrode connected to the third node N3. The capacitor C1 may store the data signal DATA transmitted to the first node N1.

The light emitting element LD may include an anode (or a first electrode) and a cathode (or a second electrode). According to some embodiments, the anode of the light emitting element LD is connected to the first voltage line VDL, and the cathode thereof is connected to the pixel driver PDC-1 through the second node N2. According to some embodiments, the cathode of the light emitting element LD may be connected to the first transistor T1. The light emitting element LD may emit light in correspondence to an amount of current flowing in the first transistor T1 of the pixel driver PDC-1.

In the present embodiments in which the first and second transistors T1 and T2 are N-type transistors, the second node N2 to which the cathode of the light emitting element LD and the pixel driver PDC-1 are connected may correspond to a drain of the first transistor T1. That is, a change in a gate-source voltage Vgs of the first transistor T1 due to the light emitting element LD may be prevented or reduced. Accordingly, because an amount of change in driving current due to the deterioration of the light emitting element LD may be reduced, an afterimage defect of a display panel due to an increase in usage time may be reduced and the lifespan thereof may be improved.

Meanwhile, FIG. 2A and FIG. 2B illustrate circuits for the pixel drivers PDC and PDC-1 according to some embodiments of the present disclosure, and as long as it is a circuit connected to the cathode of the light emitting element LD in a display panel according to some embodiments of the present disclosure, the number or arrangement relationship of transistors and the number or arrangement relationship of capacitors may be designed in various ways and are not limited to any one embodiment.

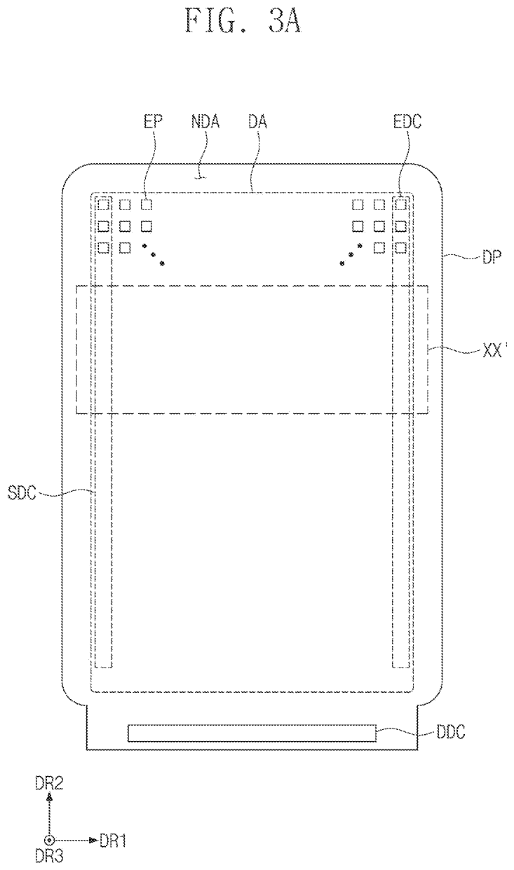

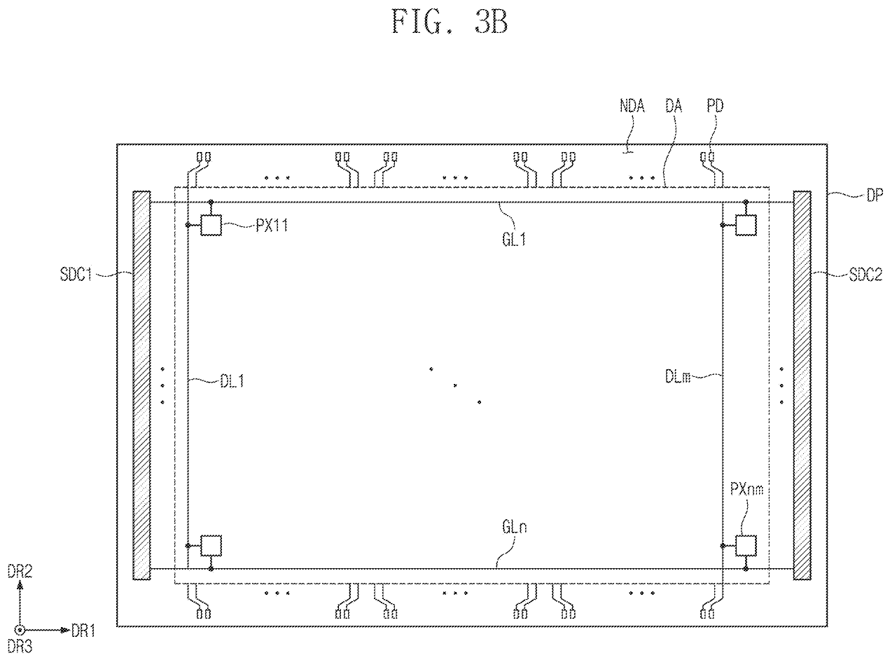

FIG. 3A and FIG. 3B are plan views schematically illustrating a display panel according to some embodiments of the present disclosure. In each of FIG. 3A and FIG. 3B, some components are omitted. Hereinafter, aspects of some embodiments of the present disclosure will be described in more detail with reference to FIG. 3A and FIG. 3B. Referring to FIG. 3A, the display panel DP according to some embodiments may divided into a display region DA and a peripheral region NDA (or a non-display region). The display region DA may include a plurality of light emitting portions EP.

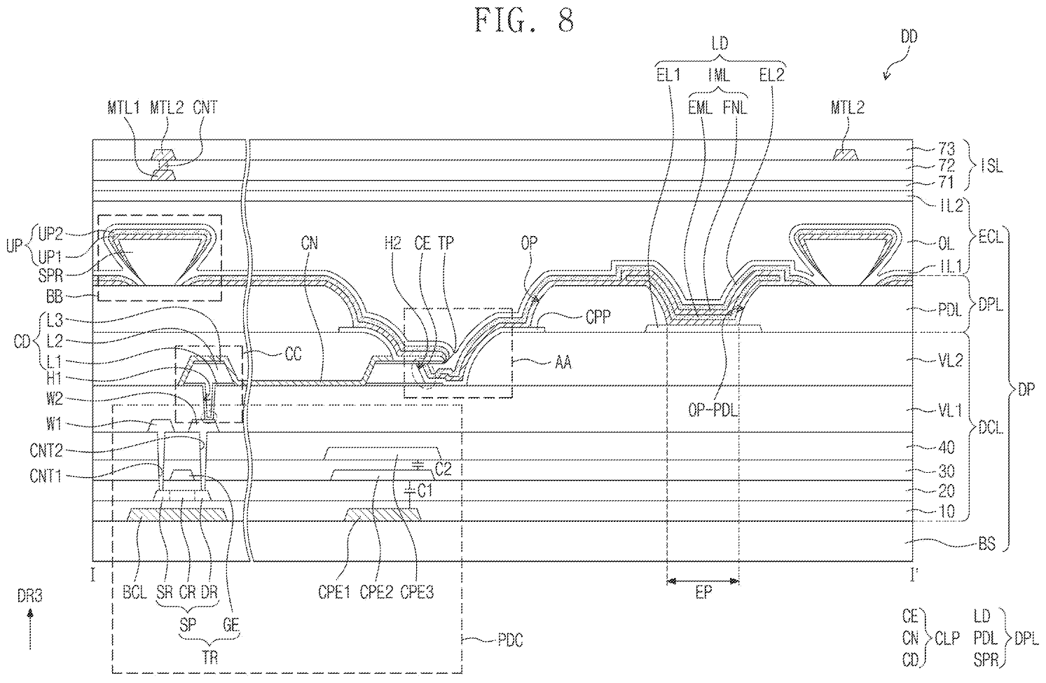

The light emitting portions EP may be regions respectively emitted by the pixels PXij (see FIG. 1). For example, each of the light emitting portions EP may be a portion corresponding to a light emitting opening OP-PDL (see FIG. 8) to be described later.

The peripheral region NDA may be located adjacent to the display region DA. According to some embodiments, the peripheral region NDA is illustrated as having a shape surrounding the display region DA. However, this is merely an example, and the peripheral region NDA may be located on one side of the display region DA, or may be omitted, and is not limited to any one embodiment.

Referring to FIG. 3A, according to some embodiments, a scan driver SDC, an emission driver EDC, and a data driver DDC may be mounted on a display panel DP. According to some embodiments, the scan driver SDC and the emission driver EDC may be located in the display region DA, and the data driver DDC may be located in the peripheral region NDA.

The scan driver SDC and the emission driver EDC may overlap, on a plane, some light emitting portions EP among the light emitting portions EP located in the display region DA. For example, the scan driver SDC and the emission driver EDC may overlap light emitting portions EP adjacent to each of both sides of the display region DA which are opposite to each other in a first direction DR1.

Below the light emitting portions EP located in the display region DA adjacent to the peripheral region NDA, the aforementioned pixel drivers PDC may not be utilized. Therefore, below the light emitting portions EP located in the display region DA adjacent to the peripheral region NAA, circuits constituting the scan driver SDC and the emission driver EDC may be utilized. According to some embodiments, because the scan driver SDC and the emission driver EDC are not located in the peripheral region NDA, but located in the display region DA, the area of the peripheral region NDA may be reduced. Accordingly, a display device with a thin bezel portion may be implemented.

According to some embodiments, the data driver DDC may be provided in the form of a separate driving chip independent from the display panel DP and be connected to the display panel DP. However, this is merely an example, and the data driver DDC may be provided in the same process with the scan driver SDC so as to constitute the display panel DP, and is not limited to any one embodiment.

Meanwhile, unlike what is illustrated in FIG. 3A, the scan driver SDC may be provided as two portions separated from each other. Two scan drivers SDC may be arranged to be spaced apart from each other in the first direction DR1. Alternatively, two or more scan driver SDC may be provided, and is not limited to any one embodiment.

As illustrated in FIG. 3B, according to some embodiments, the display panel DP may include a plurality of scan drivers SDC1 and SDC2. The scan drivers SDC1 and SDC2 are illustrated, as an example, as including a first scan driver SDC1 and a second scan driver SDC2 arranged to be spaced apart from each other in the first direction DR1.

The first scan driver SDC1 may be connected some of scan lines GL1 to GLn, and the second scan driver SDC2 may be connected others of the scan lines GL1 to GLn. For example, the first scan driver SDC1 may be connected odd-numbered scan lines among the scan lines GL1 to GLn, and the second scan driver SDC2 may be connected even-numbered scan lines among the scan lines GL1 to GLn.

For ease of description, FIG. 3B illustrates pads PD of data lines DL1 to DLm. The pads PD may be defined at ends of the data lines DL1 to DLm. The data lines DL1 to DLm may be connected to the data driver DDC (see FIG. 3A) through the pads PD.

According to some embodiments of the present disclosure, the pads PD may be divided and arranged at positions spaced apart from each other with the display region DA interposed therebetween in the peripheral region NDA. For example, some of the pads PD may be located on an upper side, that is, a side adjacent to the first scan line GL1 among the scan lines GL1 to GLn, and others of the pads PD may be located on a lower side, that is, a side adjacent to the last scan line GLn among the scan lines GL1 to GLn. According to some embodiments, pads PD connected to odd-numbered data lines among the data lines DL1 to DLm may be located on the upper side, and pads PD connected to even-numbered data lines among the data lines DL1 to DLm may be located on the lower side.

According to some embodiments, the display panel DP may include a plurality of upper data drivers connected to the pads PD located on the upper side and/or a plurality of lower data drivers connected to the pads PD located on the lower side. However, this is merely an example, and the display panel DP may include one upper data driver connected to the pads PD located on the upper side and/or one lower data driver connected to the pads PD located on the lower side. That is, the pads PD according to some embodiments of the present disclosure may be located on only one side of the display panel DP and be connected to a single data driver, and is not limited any one embodiment.

In addition, as described above with reference to FIG. 3A, even in the display panel DP in FIG. 3B, the scan drivers SDC1 and SDC2 may be located in the display region DA, and accordingly, some of the light emitting portions EP (see FIG. 3A) located in the display regions DA may overlap the scan drivers SDC1 and SDC2 on a plane.

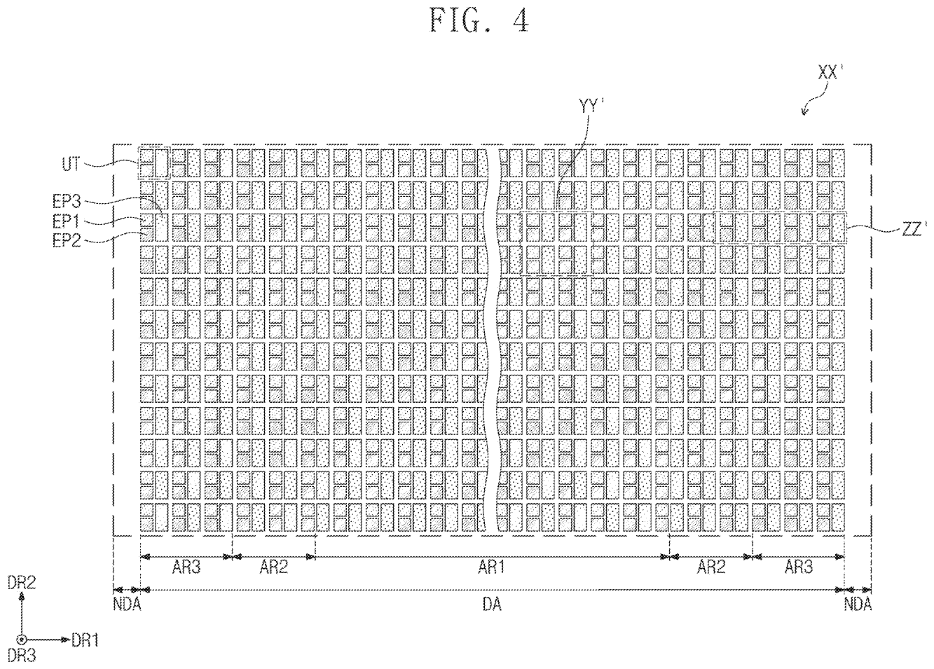

FIG. 4 is a cross-sectional view showing a portion of a display device according to some embodiments of the present disclosure. FIG. 4 is a plan view showing an enlarged portion corresponding to region XX′ of FIG. 3A.

Referring to FIG. 4, the display panel may include a display region DA and a peripheral region NDA located on an outer periphery of the display region DA. In the display region DA, a plurality of light emitting units UT may be located. The light emitting units UT may be arranged in the first direction DR1 and a second direction DR2. According to some embodiments, the light emitting units UT may be arranged in a matrix form.

In the display device DD (see FIG. 1) according to some embodiments, a display panel DP may include a first region AR1, a second region AR2, and a third region AR3, which are arranged in the first direction DR1. The first region AR1 may be located in a center portion of the display region DA, the third region AR3 may be located in an outer periphery portion of the display region DA, and the second region AR2 may be located between the first region AR1 and the third region AR3. The third region AR3 may be a region neighboring to the peripheral region NDA.

According to some embodiments, the second regions AR2 may be arranged to be spaced apart from each other in the first direction DR1 with the first region AR1 interposed therebetween, and the third regions AR3 may be arranged to be spaced apart in the first direction DR1 with the first region AR1 and the second regions AR2 interposed therebetween. The first region AR1 may be located between the second regions AR2.

The light emitting units UT may be located in the first region AR1, the second region AR2, and the third region AR3. The scan driver SDC and the emission driver EDC illustrated in FIG. 3A may be located below the light emitting units UT located in the third regions AR3.

Each of the light emitting units UT may include a plurality of light emitting portions EP1, EP2, and EP3. Each of the light emitting units UT may include a first light emitting portion EP1, a second light emitting portion EP2, and a third light emitting portion EP3, which emit light of different wavelength regions from each other. For example, the first light emitting portion EP1 may be a portion which emits red light, the second light emitting portion EP2 may be a portion which emits green light, and the third light emitting portion EP3 may be a portion which emits blue light. However, the embodiments of the present disclosure are not limited thereto, and configurations of the light emitting portions may be differently combined according to color characteristics required of the display device.

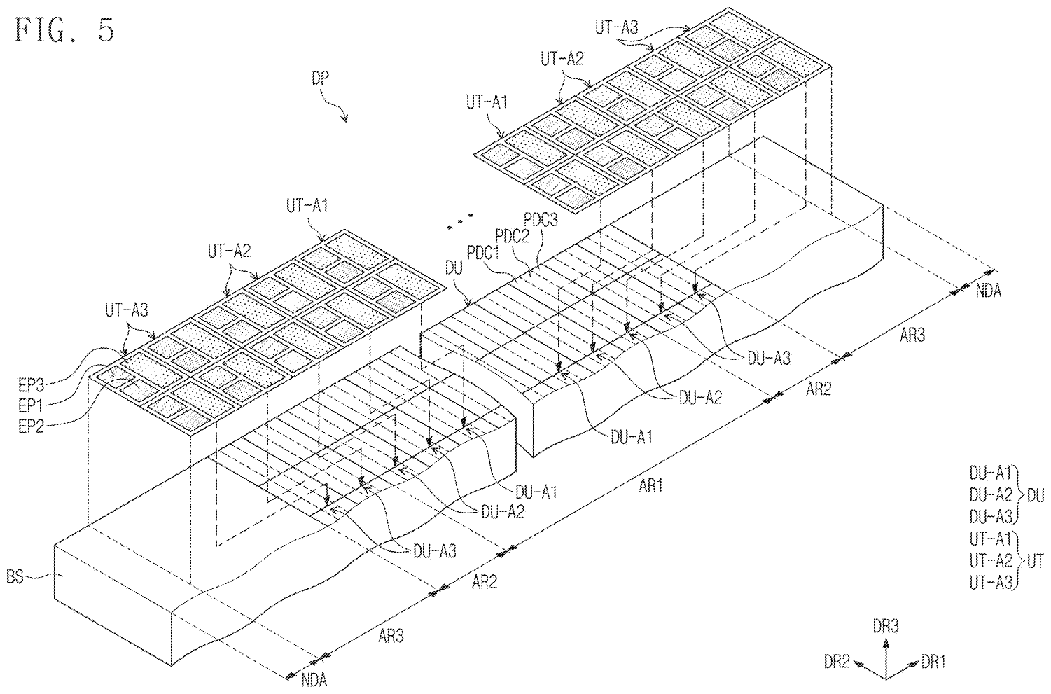

FIG. 5 is an exploded perspective view showing an enlarged portion of a display panel according to some embodiments of the present disclosure. Referring to FIG. 5. a display panel DP according to some embodiments may include a base layer BS, driving units DU located on the base layer BS, and a plurality of light emitting units UT located on the driving units DU.

Each of the driving units DU may include a plurality of pixel drivers PDC1, PDC2, and PDC3. A first pixel driver PDC1, a second pixel driver PDC2, and a third pixel driver PDC3 may constitute one driving unit DU. According to some embodiments, a plurality of driving units DU may be arranged along the first direction DR1 and the second direction DR2.

The light emitting units UT may be located in the first to third regions AR1, AR2, and AR3 constituting the display region DA (FIG. 4), and the driving units DU may be located in the first region AR1 and the second region AR2. That is, the driving units DU are not located in the third region AR3, and may be located on a lower side of the light emitting units UT in the first region AR1 and the second region AR2.

FIG. 5 illustrates the connection relationship of the light emitting units UT and the driving units DU connected corresponding to the light emitting units UT. The connection between the light emitting unit UT and the driving unit DU is illustrated with a dotted arrow. A first light emitting unit UT-A1 located in the first region AR1 may be electrically connected to a corresponding first driving unit DU-A1 located in the first region AR1, and a third light emitting unit UT-A3 located in the third region AR3 may be electrically connected to a corresponding third driving unit DU-A3 located in the second region AR2. A second light emitting unit UT-A2 located in the second region AR2 may be electrically connected to a corresponding second driving unit DU-A2 located in the first region AR1. The driving units DU may not be located in the third region AR3, and the scan driver SDC (see FIG. 3A) and the emission driver EDC (see FIG. 3A) may be located in the third region AR3.

The emission units UT may each include a first light emitting portion EP1, a second light emitting portion EP2, and a third light emitting portion EP3, and the driving units DU may each include the first pixel driver PDC1, the second pixel driver PDC2, and the third pixel driver PDC3. The first light emitting portion EP1, the second light emitting portion EP2, and the third light emitting portion EP3 may be electrically connected to the first pixel driver PDC1, the second pixel driver PDC2, and the third pixel driver PDC3, respectively.

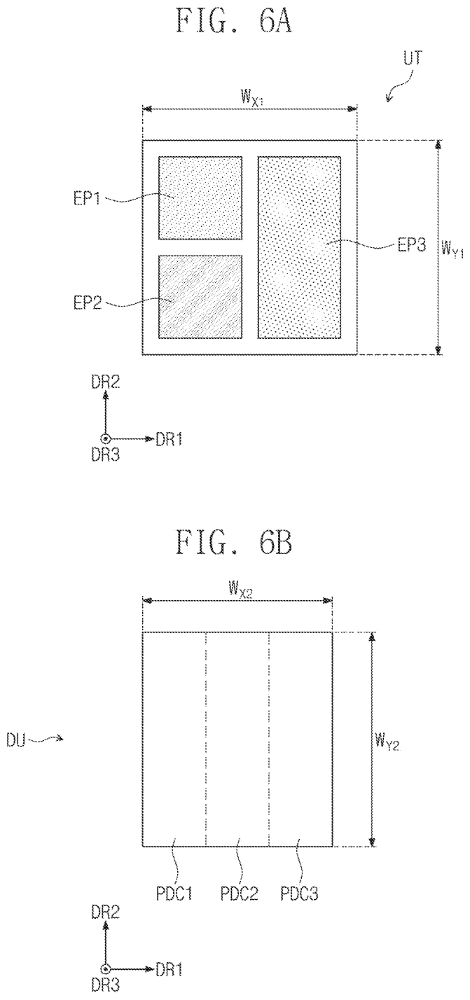

FIG. 6A is a plan view of one light emitting unit in the display panel illustrated in FIG. 5, and FIG. 6B is a plan view of one driving unit in the display panel illustrated in FIG. 5.

Referring to FIG. 6A and FIG. 6B, the light emitting unit UT may have a first width W_{X1} in the first direction DR1. The driving unit DU may have a second width W_{X2} in the first direction DR1. The second width W_{X2} may be smaller than the first width W_{X1}. A first length W_{Y1} of the light emitting unit UT in the second direction DR2 may be the same as a second length W_{Y2} of the driving unit DU in the second direction DR2. Therefore, the driving unit DU may have a smaller area than the light emitting unit UT.

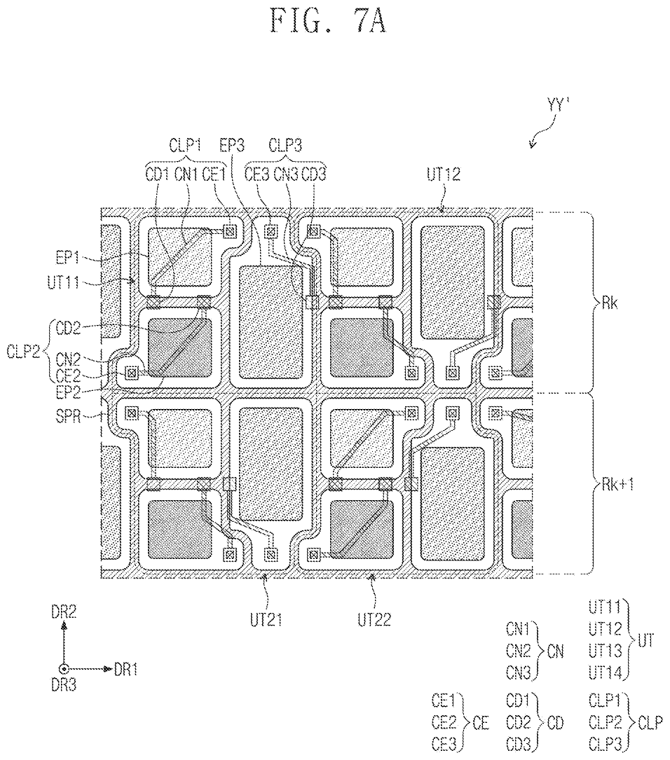

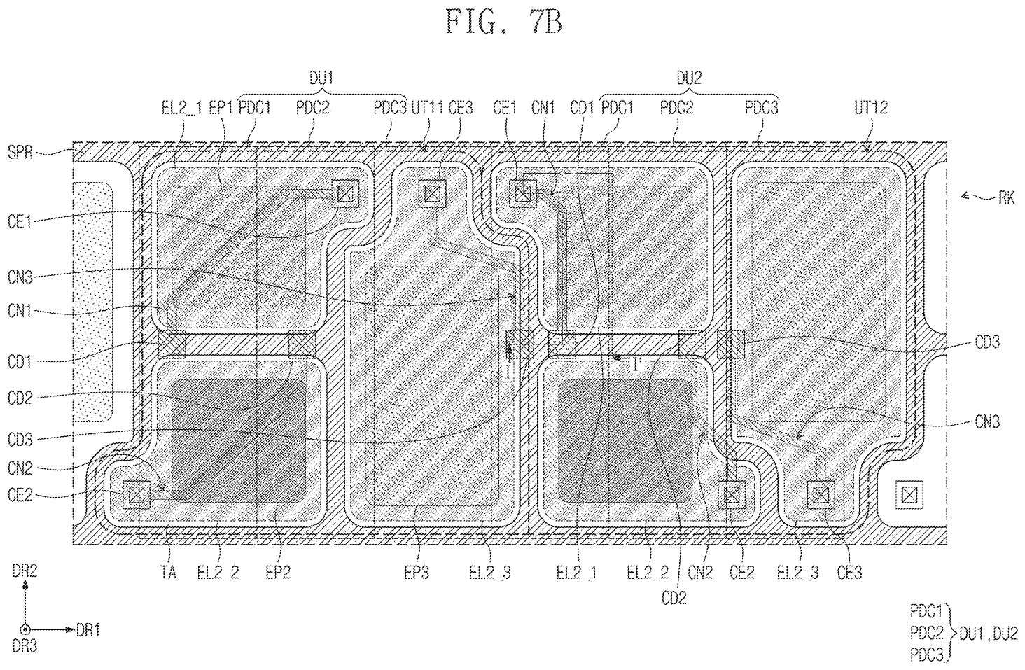

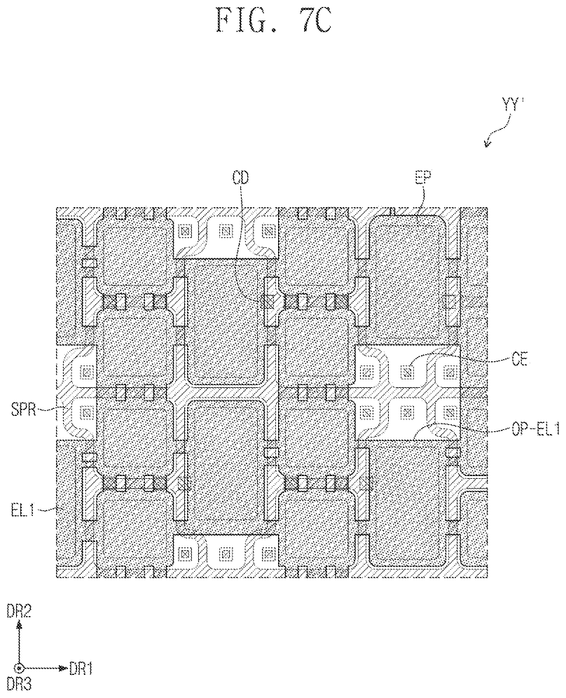

FIG. 7A to FIG. 7C are plan views of some enlarged regions of a display panel according to some embodiments of the present disclosure. FIG. 7A to FIG. 7C may be plan views of some enlarged regions of the first region AR1 (see FIG. 4) in a display region. FIG. 7A may be a plan view showing enlarged region YY′ of FIG. 4.

FIG. 7A illustrates a region in which a total of four light emitting units UT in two rows and two columns are located, and FIG. 7B illustrates an enlarged partial region illustrated in FIG. 7A. In FIG. 7C, some of the components illustrated in FIG. 7A are omitted or illustrated in an emphasized way. That is, FIG. 7C may be a plan view schematically illustrating a portion corresponding to region YY′ of FIG. 4. Hereinafter, with reference to FIG. 7A to FIG. 7C, aspects of some embodiments of the present disclosure will be described in more detail.

FIG. 7A illustrates light emitting units UT11, UT12, UT21, and UT22 in 2 rows and 2 columns. Light emitting portions of a first row Rk include light emitting portions constituting a first-row first-column light emitting unit UT11 and a first-row second-column light emitting unit UT12, and light emitting portions of a second row Rk+1 include light emitting portions constituting a second-row first-column light emitting unit UT21 and a second-row second-column light emitting unit UT22. FIG. 7B illustrates the light emitting portions of the first row Rk. Among components of the display panel, FIG. 7A to FIG. 7C illustrate a separator SPR, a plurality of light emitting portions EP1, EP2, and EP3 located in a region partitioned by the separator SPR, a connection line portion CLP, a first electrode EL1, and second electrodes EL2_1, EL2_2, and EL2_3.

As described above, each of the light emitting portions EP1, EP2, and EP3 may correspond to a light emitting opening OP-PDL (FIG. 8) to be described later. That is, the light emitting portions EP1, EP2, and EP3 may be regions from which light is emitted by the above-described light emitting element LD (see FIG. 2A), and may correspond to a unit constituting an image displayed in the display panel DP. For example, each of the light emitting portions EP1, EP2, and EP3 may correspond to a region defined by the light emitting opening OP-PDL (see FIG. 8) to be described later, particularly a region defined by a lower surface of the light emitting opening OP-PDL (see FIG. 8).

The light emitting portions EP1, EP2, and EP3 may include a first light emitting portion EP1, a second light emitting portion EP2, and a third light emitting portion EP3, which emit light of different colors from each other. For example, the first light emitting portion EP1 which emits red light, the second light emitting portion EP2 which emits green light, and the third light emitting portion EP3 which emits blue light may constitute one light emitting unit UT. The combination of colors of light emitting portions in one light emitting unit UT is not limited thereto. In addition, at least two or more of the light emitting portions EP1, EP2, and EP3 may emit light of the same color. For example, the first to third light emitting portions EP1, EP2, and EP3 may all emit blue light, or may all emit white light.

Meanwhile, according to some embodiments, the third light emitting portion EP3 may include two sub-light emitting portions spaced apart from each other in the second direction DR2. In addition, at least one of the other light emitting portions EP1 or EP2 may include sub-light emitting portions spaced apart, and the shape and arrangement of the light emitting portions EP1, EP2, and EP3 are not limited to the illustrated embodiment.

According to some embodiments as illustrated in FIG. 7A to FIG. 7C, the first light emitting portion EP1 included in each of the light emitting units UT may be spaced apart from the second light emitting portion EP2 in the second direction DR2, and the third light emitting portion EP3 may be spaced apart from the first and second light emitting portions EP1 and EP2 in the first direction DR1.

The light emitting units UT may be arranged in the first row Rk and the second row Rk+1. A row may correspond to the first direction DR1. According to some embodiments, the first row Rk may be composed of light emitting portions in the form in which the first-row first-column light emitting unit UT11 and the first-row second-column light emitting unit UT12 are repeatedly arranged. In the addition, the second row Rk+1 may be composed of light emitting portions in the form in which the second-row first-column light emitting unit UT21 and the second-row second-column light emitting unit UT22 are repeatedly arranged.

The first-row first-column light emitting unit UT11 and the second-row first-column light emitting unit UT21 may be repeatedly arranged in the second direction DR2. The first-row second-column light emitting unit UT12 and the second-row second-column light emitting unit UT22 may be repeatedly located in the second direction DR2. The second direction DR2 may correspond to a column.

The first to third light emitting portions EP1, EP2, and EP3 of the first-row first-column light emitting unit UT11 and the first to third light emitting portions EP1, EP2, and EP3 of the second-row second-column light emitting unit UT22 may have the same arrangement structure. The first to third light emitting portions EP1, EP2, and EP3 of the first-row second-column light emitting unit UT12 and the first to third light emitting portions EP1, EP2, and EP3 of the second-row first-column light emitting unit UT21 may have the same arrangement structure. Therefore, hereinafter, the composition of the first-column light emitting unit UT11 and the first-row second-column light emitting unit UT12 located in the first row Rk will be mainly described.

For ease of description, FIG. 7B illustrates a plurality of second electrodes EL2_1, EL2_2, and EL2_3, a plurality of pixel drivers PDC1, PDC2, and PDC3, and a plurality of connection wiring portions CLP1, CLP2, and CLP3 (see FIG. 7A). The second electrodes EL2_1, EL2_2, and EL2_3 may be separated from each other by the separator SPR and be electrically disconnected. According to some embodiments, one light emitting unit UT may include three light emitting portions EP1, EP2, and EP3. Accordingly, the light emitting unit UT may include three second electrodes EL2_1, EL2_2, and EL2_3 (hereinafter, first to third cathodes), three pixel drivers PDC1, PDC2, and PDC3, and three connection wiring portions CLP1, CLP2, and CLP3. However, this is merely an example, and the number and arrangement of the light emitting unit UT may be designed in various ways, and are not limited to any one embodiment.

The first to third pixel drivers PDC1, PDC2, and PDC3 are electrically connected to light emitting elements constituting the first to third light emitting portions EP1, EP2, and EP3, respectively. In the present disclosure, being “connected” includes not only a case of being connected by a direct physical contact, but also a case of being electrically connected.

The display panel may include an emission connection part CE, a driving connection part CD, and a plurality of connection wiring portions CLP including a extension wiring CN. In a display device according to some embodiments, the driving connection part CD may not overlap the light emitting portions EP1, EP2, and EP3. All of a plurality of driving connection parts CD may not overlap the entire light emitting portions EP, EP2, and EP3. The driving connection part CD is located in a first hole H1 (FIG. 8) defined in a first insulation layer VL1 (see FIG. 8) among components of the display device to be described later, and the first hole H1 (FIG. 8) in which the driving connection part CD is located may not overlap the entire light emitting portions EP, EP2, and EP3. Accordingly, a step portion by the first hole H1 (FIG. 8) and the driving connection part CD located in the first hole H1 (FIG. 8) may not overlap the light emitting portions EP, EP2, and EP3. Accordingly, external light reflection due to a step on a lower side of the light emitting portions EP, EP2, and EP3 may be reduced, and stains and the like due to visual recognition of reflected light may be reduced, so that the display device according to some embodiments may exhibit relatively excellent display quality.

The connection line portion CLP may include a first connection line portion CLP1 connected to the first light emitting portion EP1, a second connection line portion CLP2 connected to the second light emitting portion EP2, and a third connection line portion CLP3 connected to the third light emitting portion EP3.

Each of the first connection wiring portions CLP1 may include a first emission connection part CE1, a first driving connection part CD1 spaced apart from the first emission connection part CE1, and a first extension wiring CN1 extended between the first emission connection part CE1 and the first driving connection part CD1. The first emission connection part CE1 may be located on one side of the first extension wiring CN1, and the first driving connection part CD1 may be located on the other side of the first extension wiring CN1. The one side of the first extension wiring CN1 may overlap the first emission connection part CE1, and the other side of the first extension wiring CN1 may overlap the first driving connection part CD1.

Each of the second connection wiring portions CLP2 may include a second emission connection part CE2, a second driving connection part CD2 spaced apart from the second emission connection part CE2, and a second extension wiring CN2 extended between the second emission connection part CE2 and the second driving connection part CD2. The second emission connection part CE2 may be located on one side of the second extension wiring CN2, and the second driving connection part CD2 may be located on the other side of the second extension wiring CN2. The one side of the second extension wiring CN2 may overlap the second emission connection part CE2, and the other side of the second extension wiring CN2 may overlap the second driving connection part CD2.

Each of the third connection wiring portions CLP3 may include a third emission connection part CE3, a third driving connection part CD3 spaced apart from the third emission connection part CE3, and a third extension wiring CN3 extended between the third emission connection part CE3 and the third driving connection part CD3. The third emission connection part CE3 may be located on one side of the third extension wiring CN3, and the third driving connection part CD3 may be located on the other side of the third extension wiring CN3. The one side of the third extension wiring CN3 may overlap the third emission connection part CE3, and the other side of the third extension wiring CN3 may overlap the third driving connection part CD3.

The first, second, and third driving connection parts CD1, CD2, and CD3 may be arranged in the first direction DR1 at a central portion of the first row Rk. For example, when viewed on a plane, some driving connection parts may overlap the separator SPR. However, the embodiments of the present disclosure are not limited thereto, and the first, second, and third driving connection parts CD1, CD2, and CD3 may not be arranged forming one row, but may be located at an arbitrary position in a portion not overlapping the light emitting portions EP1, EP2, and EP3.

The first, second, and third driving connection parts CD1, CD2, and CD3 may be respectively connected to pixel drivers PDC1, PDC2, and PDC3 to be described with reference to FIG. 7B and the like below.

When viewed on a plane, the first, second, and third emission connection parts CE1, CE2, and CE3 may be spaced apart from the light emitting portions EP1, EP2, and EP3, thereby not overlapping the light emitting portions EP1, EP2, and EP3. The first, second, and third emission connection parts CE1, CE2, and CE3 may be connected to the second electrodes EL2_1, EL2_2, and EL2_3 (hereinafter, referred to as cathodes) of the light emitting element LD (see FIG. 8) constituting the first, second, and third light emitting portions EP1, EP2, and EP3 to be described with reference to FIG. 7B and the like below.

FIG. 7B is an enlarged view of light emitting units located in a first row illustrated in FIG. 7A. Referring to FIG. 7B, the light emitting units UT11 and UT12 may each include a plurality of cathodes EL2_1, EL2_2, and EL2_3. The cathodes EL2_1, EL2_2, and EL2_3 may respectively overlap the first, second, and third light emitting portions EP1, EP2, and EP3. The cathodes EL2_1, EL2_2, and EL2_3 may be separated from each other by the separator SPR and be electrically disconnected.

In each of the light emitting units UT11 and UT12, the cathodes EL2_1, EL2_2, and EL2_3 may include a first cathode EL2_1 overlapping the first light emitting portion EP1, a second cathode EL2_2 overlapping the second light emitting portion EP2, and a third cathode EL2_3 overlapping the third light emitting portion EP3. The first to third cathodes EL2_1, EL2_2, and EL2_3 may each correspond to a second electrode EL2 illustrated in FIG. 8.

The first cathode EL2_1 may be a second electrode of a light emitting element forming the first light emitting portion EP1, the second cathode EL2_2 may be a second electrode of the light emitting element forming the second light emitting portion EP2, and the third cathode EL2_3 may be a second electrode of a light emitting element forming the third light emitting portion EP3.

When viewed on a plane, the first to third cathodes EL2_1, EL2_2, and EL2_3 may each have a larger area than the first, second, and third light emitting portions EP1, EP2, and EP3. The first, second, and third light emitting portions EP1, EP2, and EP3 may have quadrangular shapes, and the first to third cathodes EL2_1, EL2_2, and EL2_3 may have atypical shapes.

On a plane, the first to third cathodes EL2_1, EL2_2, and EL2_3 may each be provided with a larger area than the first, second, and third light emitting portions EP1, EP2, and EP3, so that portions of the first to third cathodes EL2_1, EL2_2, and EL2_3 may overlap tip regions TA. Portions of the first to third cathodes EL2_1, EL2_2, and EL2_3 which are each provided with a larger area than the light emitting portions EP1, EP2, and EP3 and which overlap the tip regions TA may respectively overlap the emission connection parts CE1, CE2, and CE3.

When viewed on a plane, in each of the light emitting units UT11 and UT12, portions of the first to third cathodes EL2_1, EL2_2, and EL2_3 may respectively overlap the first emission connection part CE1, the second emission connection part CE2, and the third emission connection part CE3.

The display panel DP may include a plurality of driving units DU arranged in the first direction DR1. The driving units DU may each include a first pixel driver PDC1, a second pixel driver PDC2, and a third pixel driver PDC3. The first, second, and third pixel drivers PDC1, PDC2, and PDC3 may be sequentially arranged in the first direction DR1. In FIG. 7B, regions on a plane of the first, second, and third pixel drivers PDC1, PDC2, and PDC3 are illustrated as quadrangles with dotted lines.

The first, second, and third pixel drivers PDC1, PDC2, and PDC3 may substantially have the same configuration as the pixel driver PDC illustrated in FIG. 2A. The first, second, and third pixel drivers PDC1, PDC2, and PDC3 may be electrically connected to light emitting elements constituting the first, second, and third light emitting portions EP1, EP2, and EP3, respectively. The first, second, and third pixel drivers PDC1, PDC2, and PDC3 may be located lower than the light emitting elements.

On a plane defined by the first direction axis DR1 and the second direction axis DR2, each of the driving units DU may have a smaller area than each of the light emitting units UT11 and UT12. Corresponding driving units DU electrically connected to the light emitting units UT11 and UT12 may be partially shifted and located in a direction parallel to the first direction DR1 compared to the light emitting units UT11 and UT12.

FIG. 7B shows the light emitting units UT11 and UT12 located in the first region AR1 (see FIG. 5) and the driving units DU connected thereto, and in each of the driving units DU located in the first region AR1 (see FIG. 5), the first pixel driver PDC1 may overlap the first light emitting portion EP1 and the second light emitting portion EP2, and the second pixel driver PDC2 may overlap the first light emitting portion EP1 and the second light emitting portion EP2. In each of the driving units DU, the third pixel driver PDC3 may overlap the third light emitting portion EP3.

However, this is merely an example, and depending on the arrangement position of the driving units DU, the first, second, and third pixel drivers PDC1, PDC2, and PDC3 may overlap various portions of the first, second, and third light emitting portions EP1, EP2, and EP3.

The first-row first-column light emitting unit UT11 may be connected to a first driving unit DU1, and the first-row second-column light emitting unit UT12 may be connected to a second driving unit DU2. The first-row first-column light emitting unit UT11 and the first-row second-column light emitting unit UT12 and the first and second driving units DU1 and DU2 may be connected to each other by the first, second, and third connection line portion CLP1, CLP2, and CLP3.

Referring to FIG. 7A and FIG. 7B, the connection wiring portions CLP may be provided in plurality and be arranged to be spaced apart from each other. The connection line portion CLP may electrically connect a pixel driver and a light emitting element. For example, the connection line portion CLP may correspond to a node (see N4 of FIG. 2A or N2 of FIG. 2B) in which the light emitting element LD (see FIG. 8) is connected to the pixel driver PDC (see FIG. 8).

The connection line portion CLP may include the emission connection part CE and the driving connection part CD. The driving connector CD may be a portion of the extension wiring CN that is connected to the pixel drivers PDC1, PDC2, and PDC3. According to some embodiments, the driving connection part CD may be connected to one electrode of a transistor constituting the pixel drivers PDC1, PDC2, and PDC3. For example, the driving connection part CD may be connected to a drain of the sixth transistor T6 illustrated in FIG. 2A or the drain of the first transistor T1 illustrated in FIG. 2B. Accordingly, the position of the driving connection part CD may correspond to the position of a transistor TR (see FIG. 5) physically connected to the connection line portion CLP of a pixel driver. The emission connection part CE may be a portion of the connection line portion CLP that is connected to a light emitting element. According to some embodiments, the emission connection part CE may be connected to the second electrode EL2 (see FIG. 8) of a light emitting element.

The light emitting units UT11 and UT12 may each include at least a portion of the first to third extension wirings CN1, CN2, and CN3. The first connection line portion CLP1 may connect a light emitting element forming the first light emitting portion EP1 and the first pixel driver PDC1, the second connection line portion CLP2 may connect a light emitting element forming the second light emitting portion EP2 and the second pixel driver PDC2, and the third connection line portion CLP3 may connect a light emitting element forming the third light emitting portion EP3 and the third pixel driver PDC3.

For example, the first to third connection wiring portions CLP1, CLP2, and CLP3 may connect the first to third cathodes EL2_1, EL2_2, and EL2_3 and the first to third pixel drivers PDC1, PDC2, and PDC3, respectively. The first connection line portion CLP1 may include the first driving connection part CD1 connected to the first pixel driver PDC1 and the first emission connection part CE1 connected to the first cathode EL2_1. The second connection line portion CLP2 may include the second driving connection part CD2 connected to the second pixel driver PDC2 and the second emission connection part CE2 connected to the second cathode EL2_2. The third connection line portion CLP3 may include the third driving connection part CD3 connected to the third pixel driver PDC3 and the third emission connection part CE3 connected to the third cathode EL2_3.

The first to third driving connection parts CD1, CD2, and CD3 may be arranged along the first direction DR1. As described above, the first to third driving connection parts CD1, CD2, and CD3 may correspond to positions of connection transistors constituting the first to third pixel drivers PDC1, PDC2, and PDC3, respectively. In one pixel, a connection transistor may be a transistor including, as one electrode, a connection node to which a pixel driver and a light emitting element are connected, and may correspond to, for example, the sixth transistor T6 of FIG. 2A or the first transistor T1 of FIG. 2B. According to some embodiments of the present disclosure, regardless of the shape, size, and emission color of a light emitting portion, the shape, position, and arrangement of a pixel driver of all pixels may be simply configured and designed.

According to some embodiments, the first to third emission connection parts CE1, CE2, and CE3 may be located at positions not overlapping the light emitting portions EP1, EP2, and EP3 on a plane. As to be described later, the emission connection part CE (see FIG. 8) of the connection line portion CLP is a portion to which the light emitting element LD (see FIG. 8) is connected and in which a tip portion TP (see FIG. 8) is defined, and thus may be provided at a position not overlapping the light emitting opening OP-PDL (see FIG. 8). That is, in each of the cathodes EL2_1, EL2_2, and EL2_3, the emission connection parts CE1, CE2, and CE3 may be located at positions spaced apart from the light emitting portions EP1, EP2, and EP3, and the cathodes EL2_1, EL2_2, and EL2_3 may include some regions protruding from the light emitting portions EP1, EP2, and EP3 on a plane in order to be connected to the connection wiring portions CLP1, CLP2, and CLP3 at positions at which the emission connection parts CE1, CE2, and CE3 are located.

For example, the first cathode EL2_1 may include a protruding portion in a shape protruding from the first light emitting portion EP1 at a position not overlapping the first light emitting portion EP1 in order to be connected to the first connection line portion CLP1 at a position at which the first emission connection part CE1 is located, and the first emission connection part CE1 may be provided in the protruding portion.

In addition, the first pixel driver PDC1, particularly the first driving connection part CD1, which is a position at which the first connection line portion CLP1 is connected to the transistor TR, may be located at a position not overlapping the first light emitting portion EP1 on a plane. According to some embodiments, the first extension wiring CN1 may be located overlapping the first light emitting portion EP1. The first extension wiring CN1 may be formed of a transparent conductive material. The first cathode EL2_1 and the first pixel driver PDC1 spaced apart by the first extension wiring CN1 may be easily connected.

Meanwhile, the third pixel driver PDC3, particularly the third driving connection part CD3, which is a position at which the third connection line portion CLP3 is connected to the transistor TR, may be located at a position not overlapping the third emission connection part CE3 and the third light emitting portion EP3 on a plane. According to some embodiments as illustrated in FIG. 7A and FIG. 7B, the third extension wiring CN3 is illustrated as not overlapping the third light emitting portion EP3, but the embodiments of the present disclosure are not limited thereto, and the third extension wiring CN3 included in a light emitting unit located in some regions AR2 and AR3 (see FIG. 4) may be arranged to overlap the third light emitting portion EP3.

In FIG. 7C, light emitting portions EP, the driving connection part CD, and the emission connection part CE are briefly shown. Meanwhile, referring to FIG. 7C, a first electrode EL1 (hereinafter, an anode) of a light emitting element according to some embodiments of the present disclosure may be commonly provided to the plurality of light emitting portions EP. That is, the anode EL1 may be formed as one layer throughout the display region DA, and accordingly, the anode EL1 layer may be arranged to be overlapping the separator SPR. Alternatively, the anode EL1 of each light emitting element may be formed as an independent conductive pattern spaced apart from each other, and may be electrically connected to each other through another conductive layer, and accordingly, anode EL1 patterns may not overlap the separator SPR.

A first power voltage VDD may be applied to the anode EL1 and a common voltage may be provided to all of the light emitting portions EP. The anode EL1 may be connected to the first power line VDL (see FIG. 2A) providing the first power voltage VDD in the peripheral region NDA, or may be connected to the first power line VDL (see FIG. 2A) in the display region DA, but is not limited to any one embodiment. Meanwhile, a plurality of openings OP-EL1 may be defined in the anode EL1 according to some embodiments, and the openings may pass through the anode EL1 layer. According to some embodiments, the openings OP-EL1 may be defined overlapping the emission connection parts CE. The openings OP-EL1 of the anode EL1 layer may be located at a position not overlapping the light emitting portions EP, and may generally be defined at a position overlapping the separator SPR. The openings may facilitate the discharge of a gas generated from an organic layer located on a lower side of the anode EL1, for example, a second insulation layer VL2 (see FIG. 8) to be described later. Accordingly, in the process of manufacturing the display panel, the gas of the organic layer located in a lower portion of a light emitting element may be sufficiently discharged, and the gas discharged from the organic layer after the manufacturing is reduced, so that a rate at which the light emitting element is deteriorated may be reduced.

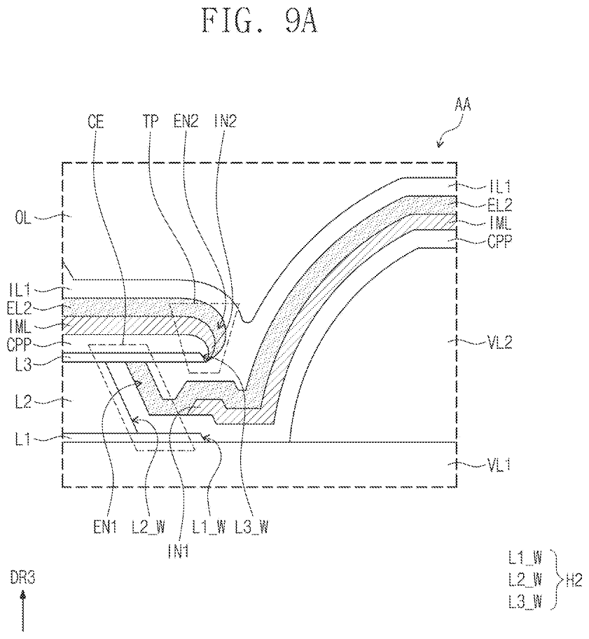

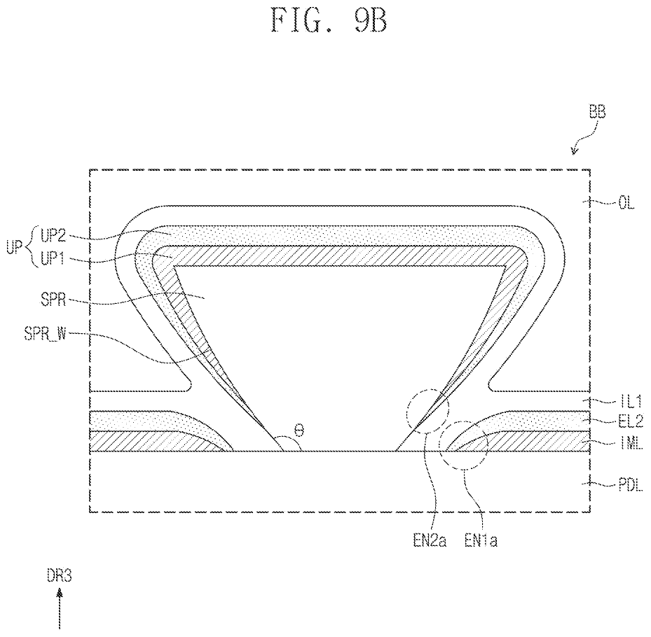

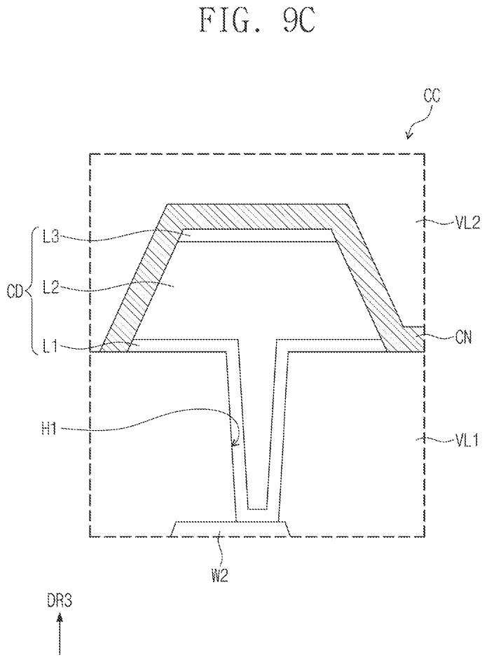

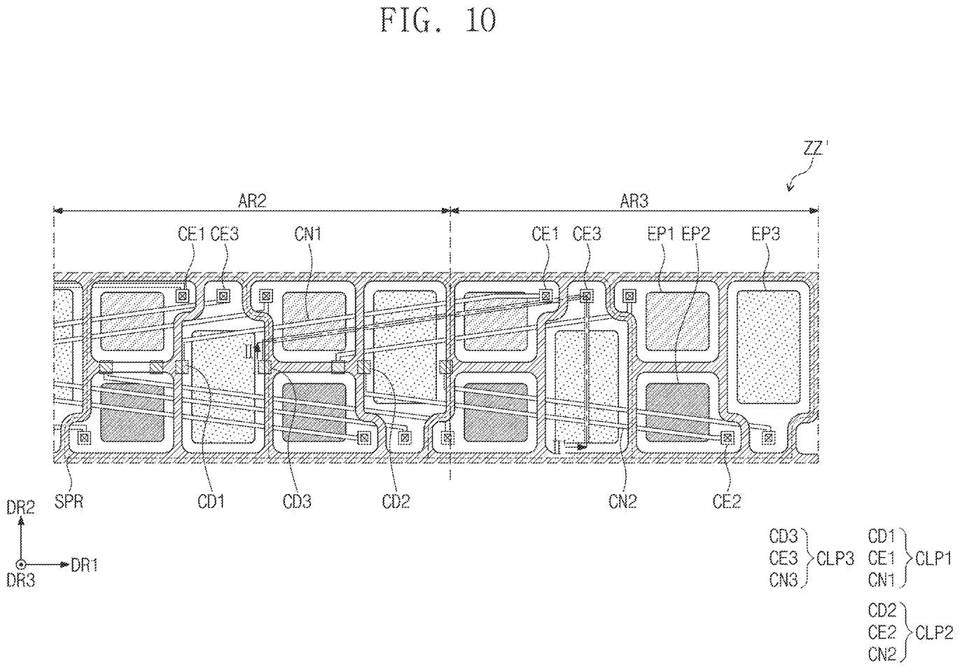

FIG. 8 is a cross-sectional view of a display device according to some embodiments of the present disclosure. FIG. 9A to FIG. 9C are each a cross-sectional view of an enlarged partial region of a display panel according to some embodiments of the present disclosure. FIG. 8 illustrates a cross-section of a display device corresponding to a portion corresponding to line I-I′ of FIG. 7B. FIG. 9A illustrates a cross-sectional view of enlarged region AA of FIG. 8, and FIG. 9B illustrates a cross-sectional view of enlarged region BB of FIG. 8. In addition, FIG. 9C illustrates a cross-sectional view of enlarged region CC of FIG. 8. Hereinafter, referring to FIGS. 8 to 9C, a display device according to some embodiments will be described.

Referring FIG. 8, a display device DD according to some embodiments may include a display panel DP and a sensing layer ISL located on the display panel DP. The display panel DP according to some embodiments may include a base layer BS, a circuit layer DCL, a display element layer DPL, and an encapsulation layer ECL.

The circuit layer DCL may include a plurality of interlayer insulation layers 10, 20, 30, and 40 located on the base layer BS, a plurality of conductive patterns and semiconductor patterns located between the interlayer insulation layers, and first and second insulation layers VL1 and VL2 in which holes H1 and H2 are defined. The conductive patterns and the semiconductor patterns may be located between the insulation layers 10, 20, 30, 40, and VL1 and constitute a pixel driver PDC. For ease of description, FIG. 8 illustrates a cross-section of any one region among regions in which one light emitting portion is located. For example, FIG. 8 may show a region in which one light emitting portion included in a light emitting unit located in the first region AR1 (see FIG. 4) is located.

The base layer BS may be a member which provides a base surface on which the pixel driver PDC is located. The base layer BS may be a rigid substrate, or a flexible substrate capable of bending, folding, rolling, and the like. The base layer BS may be a glass substrate, a metal substrate, a polymer substrate, or the like. However, the embodiments of the present disclosure are not limited thereto, and the base layer BS may be an inorganic layer, an organic layer, or a composite material layer.

The base layer BS may have a multi-layered structure. The base layer BS may include a first polymer resin layer, a silicon oxide (SiOx) layer located on the first polymer resin layer, an amorphous silicon (a-Si) layer located on the silicon oxide layer, and a second polymer resin layer located on the amorphous silicon layer. The silicon oxide layer and the amorphous silicon layer may be referred to as a base barrier layer.

The polymer resin layer may include a polyimide-based resin. In addition, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. Meanwhile, in the present disclosure, “˜˜-based” resin means that a functional group of “˜˜” is included.

Each of insulation layers, conductive layers, and semiconductor layers located on the base layer BS may be formed by coating, deposition, or the like. Thereafter, an insulation layer, a semiconductor layer, and a conductive layer may be selectively patterned through performing a photolithography process a plurality of times to form a hole in the insulation layer, or to form a semiconductor pattern, a conductive pattern, a signal line, and the like.

The circuit layer DCL may include the first to fourth interlayer insulation layers 10, 20, 30, and 40 and the pixel driver PDC sequentially stacked on the base layer BS. FIG. 8 illustrates one transistor TR and two capacitors C1 and C2 of the pixel driver PDC. The transistor TR may correspond to a transistor connected to the light emitting element LD through a connection line portion CLP, that is, a connection transistor connected to a node (the fourth node N4 of FIG. 2A, or the second node N2 of FIG. 2B) corresponding to the cathode of the light emitting element LD, and for example, may correspond to the sixth transistor T6 of FIG. 2A or the first transistor T1 of FIG. 2B. Meanwhile, according to some embodiments, other transistors constituting the pixel driver PDC may have the same structure as that of the transistor TR (hereinafter, a connection transistor) illustrated in FIG. 8. However, this is merely an example, and the other transistors constituting the pixel driver PDC may be have a different structure from that of the transistor TR, and are not limited to any one embodiment.

On the base layer BS, the first interlayer insulation layer 10 may be located. The first interlayer insulation layer 10 may be an inorganic layer and/or an organic layer, and may have a single-layered or multi-layered structure. The first interlayer insulation layer 10 may include at least one of an aluminum oxide, a titanium oxide, a silicon oxide, a silicon nitride, a silicon oxynitride, a zirconium oxide, or a hafnium oxide. According to some embodiments, the first interlayer insulation layer 10 is illustrated as a single-layered silicon oxide layer. Meanwhile, insulation layers to be described later may be inorganic layers and/or organic layers, and may have a single-layered structure or multi-layered structure. The inorganic layer may include at least one of the above-described materials, but is not limited thereto.

Meanwhile, the first interlayer insulation layer 10 may cover a lower conductive layer BCL. That is, the display panel DP may further include the lower conductive layer BCL arranged to overlap the connection transistor TR. The lower conductive layer BCL may block an electric potential due to polarization of the base layer BS from affecting the connection transistor TR. In addition, the lower conductive layer BCL may block light incident to the connection transistor TR from a lower portion. Between the lower conductive layer BCL and the base layer BS, at least one of an inorganic barrier layer or a buffer layer may be further formed.

The lower conductive layer BCL may include a reflective metal. For example, the lower conductive layer BCL may include titanium (Ti), molybdenum (Mo), an alloy containing molybdenum, aluminum (Al), an alloy containing aluminum, an aluminum nitride (AlN), tungsten (W), a tungsten nitride (WN), copper (Cu), or the like.

According to some embodiments, the lower conductive layer BCL may be connected to a source of the transistor TR through a source electrode pattern W1. In this case, the lower conductive layer BCL may be synchronized with the source of the transistor TR. However, this is merely an example, and the lower conductive layer BCL may be connected to a gate of the transistor TR, thereby being synchronized with the gate. Alternatively, the lower conductive layer BCL may be connected to another electrode and be independently applied with a constant voltage or a pulse signal. Alternatively, the lower conductive layer BCL may be provided in an isolated form from another conductive pattern. The lower conductive layer BCL according to some embodiments of the present disclosure may be provided in various forms, and is not limited to any one embodiment.

On the first interlayer insulation layer 10, the connection transistor TR may be arranged. The connection transistor TR may include a semiconductor pattern SP and a gate electrode GE. The semiconductor pattern SP may be located on the first interlayer insulation layer 10. The semiconductor pattern SP may include an oxide semiconductor. For example, the oxide semiconductor may include a transparent conductive oxide (TCO) such as an indium tin oxide (ITO), an indium zinc oxide (IZO), an indium gallium zinc oxide (IGZO), a zinc oxide (ZnO), an indium oxide (In₂O₃), or the like. However, the embodiments of the present disclosure are not limited thereto, and the semiconductor pattern may include amorphous silicon, low-temperature polycrystalline silicon, or polycrystalline silicon.

The semiconductor pattern SP may include a source region SR, a drain region DR, and a channel region CR, which are divided according to the degree of conductivity. The channel region CR may be a portion overlapping the gate electrode GE on a plane. The source region SR and the drain region DR may be portions spaced apart from each other with the channel region CR interposed therebetween. When the semiconductor pattern SP is an oxide semiconductor, the source region SR and the drain region DR may each be a reduced region. Accordingly, the source region SR and the drain region DR have a relatively high reduced metal content compared to the channel region CR. Alternatively, when the semiconductor pattern SP is polycrystalline silicon, the source region SR and the drain region DR may each be a region doped to a high concentration.

The source region SR and the drain region DR may have relatively high conductivity compared to the channel region CR. The source region SR may correspond to a source electrode of the connection transistor TR, and the drain region DR may correspond to a drain electrode of the connection transistor TR. As illustrated in FIG. 8, a separate source electrode pattern W1 and a separate drain electrode pattern W2 respectively connected to the source region SR and the drain region DR may be further provided. For example, the separate source electrode pattern W1 and the separate drain electrode pattern W2 may each be formed as a single body with one of lines constituting a pixel driver (see FIG. 2A and FIG. 2B), and are not limited to any one embodiment.

The second interlayer insulation layer 20 commonly overlaps a plurality of pixels, and may cover the semiconductor pattern SP. The second interlayer insulation layer 20 may be an inorganic layer and/or an organic layer, and may have a single-layered or multi-layered structure. The second interlayer insulation layer 20 may include at least one of an aluminum oxide, a titanium oxide, a silicon oxide, a silicon nitride, a silicon oxynitride, a zirconium oxide, or a hafnium oxide. According to some embodiments, the second interlayer insulation layer 20 may be a single-layered silicon oxide layer.

The gate electrode GE may be located on the second interlayer insulation layer 20. The gate electrode GE may correspond to the gate of the connection transistor TR. In addition, the gate electrode GE may be located on an upper side of the semiconductor pattern SP. However, this is merely an example, and the gate electrode GE may be located on a lower side of the semiconductor pattern SP, and is not limited to any one embodiment.

The gate electrode GE may include titanium (Ti), silver (Ag), molybdenum (Mo), aluminum (Al), an aluminum nitride, tungsten (W), a tungsten nitride (WN), copper (Cu), an alloy thereof, or the like, but is not limited thereto.

On the gate electrode GE, the third interlayer insulation layer 30 may be formed. The third interlayer insulation layer 30 may be an inorganic layer and/or an organic layer, and may have a single-layered or multi-layered structure. The fourth interlayer insulation layer 40 may include at least one of an aluminum oxide, a titanium oxide, a silicon oxide, a silicon nitride, a silicon oxynitride, a zirconium oxide, or a hafnium oxide.

Among a plurality of conductive patterns W1, W2, CPE1, CPE2, and CPE3, a first capacitor electrode CPE1 and a second capacitor electrode CPE2 constitute a first capacitor C1. The first capacitor electrode CPE1 and the second capacitor electrode CPE2 may be spaced apart from each other with the first interlayer insulation layer 10 and the second interlayer insulation layer 20 interposed therebetween.

According to some embodiments of the present disclosure, the first capacitor electrode CPE1 and the lower conductive layer BCL may have a shape of a single body. In addition, the second capacitor electrode CPE2 and the gate electrode GE may have a shape of a single body.

On the third interlayer insulation layer 30, a third capacitor electrode CPE3 may be formed. The third capacitor electrode CPE3 may be spaced apart from the second capacitor electrode CPE2 with the third interlayer insulation layer 30 interposed therebetween, and may overlap on a plane. The third capacitor electrode CPE3 may constitute the second capacitor electrode CPE2 and a second capacitor C2.

On the third interlayer insulation layer 30 and/or the third capacitor electrode CPE3, the fourth interlayer insulation layer 40 may be positioned. The fourth interlayer insulation layer 40 may be an inorganic layer and/or an organic layer, and may have a single-layered or multi-layered structure. The fourth interlayer insulation layer 40 may include at least one of an aluminum oxide, a titanium oxide, a silicon oxide, a silicon nitride, a silicon oxynitride, a zirconium oxide, or a hafnium oxide.

On the fourth interlayer insulation layer 40, the source electrode pattern W1 and the drain electrode pattern W2 may be positioned. The source electrode pattern W1 may be connected to a source region SR of the connection transistor TR through a first contact-hole CNT1, and the source electrode pattern W1 and the source region SR of the semiconductor pattern SP may function as a source of the connection transistor TR. The drain electrode pattern W2 may be connected to a drain region DR of the connection transistor TR through a second contact-hole CNT2, and the drain electrode pattern W2 and the drain region DR of the semiconductor pattern SP may function as a drain of the connection transistor TR.

On the source electrode pattern W1 and the drain electrode pattern W2, the first insulation layer VL1 may be located. On the first insulation layer VL1, the connection line portion CLP may be located. The connection line portion CLP may electrically connect the pixel driver PDC and the light emitting element LD. That is, the connection line portion CLP may electrically connect the connection transistor TR and the light emitting element LD. The connection line portion CLP may be a connection node for connecting the pixel driver PDC and the light emitting element LD. That is, the connection line portion CLP may correspond to the fourth node N4 (see FIG. 2A) illustrated in FIG. 2A, or may correspond to the second node N2 (see FIG. 2B) illustrated in FIG. 2B. Meanwhile, this is merely an example, and as long as the connection line portion CLP can be connected to the light emitting element LD, the connection line portion CLP may be defined as a connection node with various elements among elements constituting the pixel driver PDC according to a design of the pixel driver PDC, and is not limited to any one embodiment.

In the first insulation layer VL1, a plurality of first holes H1 may be defined. In the first hole H1, a driving connection part CD may be located. The driving connection part CD may be included in the connection line portion CLP. The driving connection part CD may be connected to the drain region DR of the semiconductor pattern SP by the drain electrode pattern W2. The driving connection part CD may have a structure in which a plurality of layers L1, L2, and L3 are stacked. The driving connection part CD is arranged while filling the first hole H1, and may have a shape protruding in the third direction DR3 in a portion overlapping the first hole H1.

The first hole H1 may be defined not overlapping a light emitting portion EP. FIG. 8 illustrates only one first hole H1 and only one light emitting portion EP, all of the plurality of first holes H1 defined in the first insulation layer VL1 may not overlap a plurality of light emitting portions EP.

An extension wiring CN may cover the driving connection part CD. The extension wiring CN covers the entire upper and side surfaces of the driving connection part CD, and may be arranged to extend to an emission connection part CE. Between the driving connection part CD and a correspondingly connected emission connection part CE, a portion of the extension wiring CN may be directly located on the first insulation layer VLi.

The extension wiring CN may include a transparent conductive material. The extension wiring CN may be a transparent conductive layer, and may include, for example, a transparent conductive oxide such as indium tin oxide (ITO), indium zinc oxide (IZO), zinc oxide (ZnO), indium zinc tin oxide (IZTO), or the like. In addition, the extension wiring CN may include a conductive polymer such as PEDOT, a metal nanowire, graphene, or the like.

The driving connection part CD does not overlap the light emitting portion EP, and may overlap a partition structure. The partition structure may be for separating the plurality of light emitting portions EP. For example, in the present disclosure, the partition structure may refer to a pixel definition layer PDL or a separator SPR, or may refer to a stacked structure in which the pixel definition layer PDL and the separator SPR are stacked.

The driving connection part CD may overlap the pixel definition layer PDL. In addition, a portion of the driving connection part CD may overlap the separator SPR. However, the embodiments of the present disclosure are not limited thereto, and among a plurality of driving connection parts CD, some driving connection parts may not overlap the separator SPR.

On the connection line portion CLP, the second insulation layer VL2 may be located. The second insulation layer VL2 may be located on the first insulation layer VL1 and cover the connection line portion CLP. The first insulation layer VL1 and the second insulation layer VL2 may each be an organic layer. For example, the first insulation layer VL1 and the second insulation layer VL2 may each include a general purpose polymer such as benzocyclobutene (BCB), polyimide, hexamethyldisiloxane (HMDSO), polymethylmethacrylate (PMMA) and polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, a blend thereof, or the like.

In the second insulation layer VL2, a second hole H2 which exposes at least a portion of the connection line portion CLP may be defined. The connection line portion CLP may be electrically connected to the light emitting element LD through the portion exposed in the second hole H2 of the second insulation layer VL2. That is, the connection line portion CLP may electrically connect the transistor TR and the light emitting element LD. A detailed description thereof will be given later. Meanwhile, in the display panel DP according to some embodiments of the present disclosure, the second insulation layer VL2 may be provided in plurality, and is not limited to any one embodiment.

On the second insulation layer VL2, the display element layer DPL may be located. The display element layer DPL may include the pixel definition layer PDL, the light emitting element LD, and the separator SPR. The pixel definition layer PDL may be an organic layer. For example, the pixel definition layer PDL may include a general purpose polymer such as benzocyclobutene (BCB), polyimide, hexamethyldisiloxane (HMDSO), polymethylmethacrylate (PMMA) and polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, a blend thereof, or the like.

According to some embodiments, the pixel definition layer PDL may have properties of absorbing light, and for example, may have a black color. That is, the pixel definition layer PDL may include a black coloring agent. The black coloring agent may include a black dye and a black pigment. The black coloring agent may include carbon black, a metal such as chromium, or an oxide thereof. The pixel definition layer PDL may correspond to a light blocking pattern having light blocking properties.

In the pixel definition layer PDL, an opening OP-PDL (hereinafter, a light emitting opening) which exposes at least a portion of a first electrode EL1 to be described later may be defined. The light emitting opening OP-PDL may be provided in plurality and be arranged to correspond to each light emitting element. The light emitting opening OP-PDL may have all constituent elements of the light emitting element LD located therein overlapping each other, and may be substantially a region in which light emitted by the light emitting element LD is displayed. Accordingly, the shape of the light emitting portion EP on a plane may substantially correspond to the shape of the light emitting opening OP-PDL on a plane.

The light emitting element LD may include the first electrode EL1, a middle layer IML, and the second electrode EL2. The first electrode EL1 may be a transflective, transmissive, or reflective electrode. According to some embodiments of the present disclosure, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), a compound thereof, or the like, and a transparent or translucent electrode layer formed on the reflective layer. The transparent or translucent electrode layer may be provided with at least one selected from the group consisting of an indium tin oxide (ITO), an indium zinc oxide (IZO), an indium gallium zinc oxide (IGZO), a zinc oxide (ZnO), or an indium oxide (In₂O₃), and an aluminum-doped zinc oxide (AZO). For example, the first electrode EL1 may include a stacked structure of ITO/Ag/ITO.

According to some embodiments, the first electrode EL1 may be an anode of the light emitting element LD. That is, the first electrode EL1 may be connected to the first power line VDL (see FIG. 2A) and may be applied with the first power voltage VDD (see FIG. 2A). The first electrode EL1 may be connected to the first power line VDL in a display region DA, or may be connected to the first power line VDL in a peripheral region NDA. In the latter case, the first power line VDL may be located in the peripheral region NDA and the first electrode EL1 may have a shape extended to the peripheral region NDA.

In the cross-sectional view of FIG. 8, the first electrode EL1 is illustrated as overlapping the light emitting opening OP-PDL and not overlapping the separator SPR, but as described above with reference to FIG. 7C, the first electrode EL1 of each light emitting element may have a shape of a single body, and may have a mesh or lattice shape in which openings are defined in some regions. That is, as long as the same first power voltage VDD can be applied to the first electrode EL1 of each of a plurality of light emitting elements, the shape of the first electrode EL1 may be provided in various ways, and is not limited to any one embodiment.

The middle layer IML may be located between the first electrode EL1 and the second electrode EL2. The middle layer IML may include a light emitting layer EML and a functional layer FNL. The light emitting element LD may include the middle layer IML of various structures, and is not limited to any one embodiment. For example, the functional layer FNL may be provided as a plurality of layers, or may be provided as two or more layers spaced apart from each other with the light emitting layer EML interposed therebetween. Alternatively, according to some embodiments, the functional layer FNL may be omitted.

The light emitting layer EML may include an organic light emitting material. In addition, the light emitting layer EML may include an inorganic light emitting material, or may be provided as a mixed layer of an organic light emitting material and an inorganic light emitting material. According to some embodiments, the light emitting layers EML included in each adjacent light emitting portion EP may each include light emitting materials displaying different colors from each other. For example, the light emitting layer EML included in each light emitting portion EP may provide light of any one of blue, red, and green colors. However, the embodiments of the present disclosure are not limited thereto, and the light emitting layers EML located in all light emitting portions EP may include light emitting materials displaying the same color. In this case, the light emitting layer EML may provide blue light, or may provide white light. In addition, although embodiments in which the light emitting layer EML and the functional layer FNL have different shapes is illustrated in FIG. 8, the embodiments of the present disclosure are not limited thereto, and the light emitting layer EML and the functional layer FNL may be arranged in the same shape on a plane.

The functional layer FNL may be located between the first electrode EL1 and the second electrode EL2. For example, the functional layer FNL may be located between the first electrode EL1 and the light emitting layer EML, or be located between the second electrode EL2 and the light emitting layer EML. Alternatively, the functional layer FNL may be located both between the first electrode EL1 and the light emitting layer EML and between the second electrode EL2 and the light emitting layer EML. According to some embodiments, the light emitting layer EML is illustrated as being inserted into the functional layer FNL. However, this is merely an example, and the functional layer FNL may include a layer located between the light emitting layer EML and the first electrode EL1, and/or a layer located between the light emitting layer EML and the second electrode EL2, which may each be provided in plurality, but is not limited to any one embodiment.

The functional layer FNL may control the movement of charges between the first electrode EL1 and the second electrode EL2. The functional layer FNL may include a hole injection/transport material and/or an electron injection/transport material. The functional layer FNL may include at least one of an electron blocking layer, a hole transport layer, a hole injection layer, a hole blocking layer, an electron transport layer, an electron injection layer, or a charge generation layer.

The second electrode EL2 may be located on the middle layer IML. As described above, the second electrode EL2 may be connected to the connection line portion CLP and be electrically connected to the pixel driver PDC. That is, the second electrode EL2 may be electrically connected to the connection transistor TR through the connection line portion CLP.

As described above, the connection line portion CLP may include the driving connection part CD and the emission connection part CE. As described above, the driving connection part CD may be a portion of the connection line CLP that is connected to the pixel driver PDC, and may be a portion substantially connected to the transistor TR. According to some embodiments, the emission connection part CE of the connection line portion CLP may be a portion connected to the light emitting element LD. The emission connection part CE may be defined in a region exposed from the second insulation layer VL2, and may be a portion to which the second electrode EL2 is connected. At this time, a tip portion TP may be defined in the emission connection part CE.

Meanwhile, in the display panel DP according to some embodiments, the display element layer DPL may further include a capping pattern CPP. A portion of the capping pattern CPP may be located on the second insulation layer VL2. In addition, the capping pattern CPP may also be located on some regions of the connection line portion CLP exposed by the second hole H2 defined in the second insulation layer VL2. The capping pattern CPP may overlap the connection line portion CLP, and for example, may overlap the emission connection part CE and/or the tip portion TP.

In addition, as illustrated in FIG. 8 and FIG. 9A, when viewed on a cross-section, the capping pattern CPP may have a shape in which the connection is partially disconnected with respect to the tip portion TP in a region in which the emission connection part CE is defined. However, when viewed on a plane, the capping pattern CPP may have a shape of a single body entirely connected within a region (see FIG. 7A) defined as a closed line by a separator. Meanwhile, one end of the partially disconnected capping pattern CPP may contact a side surface of a second layer L2 of the connection line portion CLP, and the other end of the capping pattern CPP may be located in an upper portion of a third layer L3 of the connection line portion CLP and cover the tip portion TP.

The capping pattern CPP may include a semiconductor material. Accordingly, the second electrode EL2 may be electrically connected to the connection line portion CLP through the capping pattern CPP. That is, the capping pattern CPP contacts the side surface of the second layer L2 of the connection line portion CLP, and then the second electrode EL2 contacts the capping pattern CPP, so that all thereof may be electrically connected. The capping pattern CPP may be located relatively outward compared to the second layer L2 of the connection line portion CLP, and the second electrode EL2 may be electrically connected to the second layer L2 just by being connected to the capping pattern CPP instead of the side surface of the second layer L2, so that the connection between the connection line portion CLP and the second electrode EL2 may be more facilitated.

In addition, the capping pattern CPP may include a material having relatively low reactivity compared to the second layer L2 of the connection line portion CLP. For example, the capping pattern CPP may include copper (Cu), silver (Ag), a transparent conductive oxide, or the like. Because the capping pattern CPP having relatively low reactivity protects the side surface of the second layer L2 of the connection line portion CLP, it may be possible to prevent or reduce the oxidation of a material included in the second layer L2. In addition, it may also be possible to prevent or reduce a phenomenon in which a silver (Ag) component included in the first electrode EL1 layer is reduced during an etching process of patterning the first electrode EL1, and remain as particles causing defects.

According to some embodiments, the capping pattern CPP may be formed through the same process as that of the first electrode EL1 and may include the same material as that of the first electrode EL1. However, this is merely an example, and the capping pattern CPP and the first electrode EL1 may be formed through different processes and may include different materials, and are not limited to any one embodiment.

Meanwhile, according to some embodiments, the capping pattern CPP may be omitted. When the capping pattern CPP is omitted, one end of the second electrode EL2 may directly contact the side surface of the second layer L2.

Referring to FIG. 8 and FIG. 9A, the emission connection part CE of the connection line portion CLP will be described in more detail. As illustrated in FIG. 8 and FIG. 9A, a portion of the emission connection part CE, which is a portion of the connection line portion CLP, may have a three-layered structure. For example, the emission connection part CE may include a first layer L1, a second layer L2, and a third layer L3, which are sequentially stacked along the third direction DR3. The second layer L2 may include a material different from that of the first layer Li. In addition, the second layer L2 may include a material different from that of the third layer L3. The second layer L2 may be relatively thicker than the first layer Li. In addition, the second layer L2 may be relatively thicker than the third layer L3. The second layer L2 may include a highly conductive material. According to some embodiments, the second layer L2 may include aluminum (Al).

Meanwhile, the first layer L1 may include a material having a lower etch rate than that of the second layer L2. That is, the first layer L1 and the second layer L2 may be composed of materials having a high etch selectivity to each other. According to some embodiments, the first layer L1 may include titanium (Ti), and the second layer L2 may include aluminum (Al). In this case, a side surface L1_W of the first layer L1 may be defined further outside than a side surface L2_W of the second layer L2. That is, the emission connection part CE of the connection line portion CLP may have a shape in which the side surface L1_W of the first layer L1 protrudes outward from the side surface L2_W of the second layer L2. That is, the emission connection part CE of the connection line portion CLP may have a shape in which the side surface L2_W of the second layer L2 is recessed inward from the side surface L1_W of the first layer L1.

In addition, the third layer L3 may include a material having a lower etch rate than that of the second layer L2. That is, the third layer L3 and the second layer L2 may be composed of materials having a high etch selectivity to each other. According to some embodiments, the third layer L3 may include titanium (Ti), and the second layer L2 may include aluminum (Al). In this case, a side surface L3_W of the third layer L3 may be defined further outside than the side surface L2_W of the second layer L2. That is, the emission connection part CE of the connection line portion CLP may have a shape in which the side surface L3_W of the third layer L3 protrudes outward from the side surface L2_W of the second layer L2. That is, the emission connection part CE of the connection line portion CLP may have an undercut shape or an overhang structure, and the tip portion TP of the emission connection part CE may be defined by a portion of the third layer L3 that further protrudes than the second layer L2.

The second insulation layer VL2 and the pixel definition layer PDL may expose at least a portion of the tip portion TP and at least a portion of the side surface L2_W. For example, the second hole H2 which exposes one side of the connection line portion CLP may be defined in the second insulation layer VL2, and an opening OP which overlaps the second hole H2 may be defined in the pixel definition layer PDL. The planar area of the opening OP may be larger than the planar area of the second hole H2. However, the embodiments of the present disclosure are not limited thereto, and as long as at least a portion of the tip portion TP and at least a portion of the side surface L2_W are exposed, the planar area of the opening OP may be smaller than or equal to the planar area of the second hole H2.

On the pixel definition layer PDL, the middle layer IML may be located. The middle layer IML may be located on some regions of the second insulation layer VL2 exposed by the opening OP of the pixel definition layer PDL. In addition, the middle layer IML may be located on some regions of the connection line portion CLP exposed by the second hole H2 of the second insulation layer VL2. As illustrated in FIG. 9A, the middle layer IML may include one end IN1 arranged along an upper surface of the first insulation layer VL1 and the other end IN2 arranged along an upper surface of the tip portion TP. That is, on a cross-section, the middle layer IML may have a shape in which the connection is partially disconnected with respect to the tip portion TP in a region in which the emission connection part CE is defined. However, when viewed on a plane, the middle layer IML may have a shape of a single body entirely connected within a region (see FIG. 7A) defined as a closed line by a separator.

On the middle layer IML, the second electrode EL2 may be located. The second electrode EL2 may also be located on some regions of the second insulation layer VL2 exposed by the opening OP defined in the pixel definition layer PDL. In addition, the second electrode EL2 may also be located on some regions of the connection line portion CLP exposed by the second hole H2 defined in the second insulation layer VL2. As illustrated in FIG. 9A, the second electrode EL2 may include one end EN1 arranged along the capping pattern CPP located on the upper surface of the first insulation layer VL1 and the other end EN2 arranged along the upper surface of the tip portion TP. That is, when viewed on a cross-section, the second electrode EL2 may have a shape in which the connection is partially disconnected with respect to the tip portion TP in a region in which the emission connection part CE is defined. However, when viewed on a plane, the second electrode EL2 may have a shape of a single body entirely connected within a region (see FIG. 7A) defined as a closed line by a separator.

Meanwhile, one end EN1 of the second electrode EL2 may be arranged along a side surface of the second layer L2 and be located adjacent to the side surface L2_W of the second layer L2. For example, one end EN1 of the second electrode EL2 may be directly located in the capping pattern CPP, and be connected to the side surface L2_W of the second layer L2 through the capping pattern CPP. However, the embodiments of the present disclosure are not limited thereto, and the capping pattern CPP may be omitted and one end EN1 of the second electrode EL2 may be directly connected to the second layer L2.

For example, through a difference between deposition angles of the second electrode EL2 and the middle layer IML, the second electrode EL2 may be formed to directly contact the side surface L2_W of the second layer L2 exposed from the middle layer IML by the tip portion TP or to be connected through the capping pattern CPP. That is, the second electrode EL2 may be connected to the connection line portion CLP without a separate patterning process for the middle layer IML, and accordingly, the light emitting element LD may be electrically connected to the pixel driver PDC through the connection line portion CLP.

In addition, according to some embodiments, the other end IN2 of the middle layer IML and the other end EN2 of the second electrode EL2 may contact the side surface L3_W of the third layer L3. Although FIG. 9A illustrates that the other end IN2 of the middle layer IML covers the capping pattern CPP, and the other end EN2 of the second electrode EL2 covers the other end IN2 of the middle layer IML, the capping pattern CPP may directly contact the other end IN2 of the middle layer IML and the other end EN2 of the second electrode EL2 may directly contact the side surface L3_W of the third layer L3. In addition, on the contrary, at least a portion of the side L3_W of the third layer L3 may be partially exposed without being covered by the other end IN2 of the middle layer IML and/or the other end EN2 of the second electrode EL2.

Meanwhile, as described above, the display panel DP may include the separator SPR. The separator SPR may be located on the pixel definition layer PDL. According to some embodiments, the second electrode EL2 and the middle layer IML may be formed by being commonly deposited in a plurality of pixels through an open mask. At this time, the second electrode EL2 and the middle layer IML may be partitioned by the separator SPR. As described above, the separator SPR may have a closed line shape for each light emitting portion, and accordingly, the second electrode EL2 and the middle layer IML may have a shape partitioned for each light emitting portion. That is, the second electrode EL2 and the middle layer IML may be electrically independent of each adjacent pixel.

Referring to FIG. 8 and FIG. 9B, the separator SPR will be described in more detail. As illustrated in FIG. 9B, the separator SPR may have a reverse tapered shape. That is, an angle θ (hereinafter, a taper angle) formed by a side surface SPR_W of the separator SPR with respect to an upper surface of the pixel definition layer PDL may be an obtuse angle. However, this is merely an example, and as long as the separator SPR can electrically disconnect the second electrode EL2 for each pixel, the taper angle θ may be set in various ways. In addition, the separator SPR may have the same structure as that of the tip portion TP, and is not limited to any one embodiment.

According to some embodiments, the separator SPR may include a material having insulation properties, and particularly, may include an organic insulation material. The separator SPR may include an inorganic insulation material, and may be composed of multiple layers of an organic insulation material and an inorganic insulation material, and may include a conductive material according to an embodiment. That is, as long as the second electrode EL2 may be electrically disconnected for each pixel, the type of material of the separator SPR is not particularly limited.

In an upper portion the separator SPR, a dummy layer UP may be located. The dummy layer UP may include a first dummy layer UP1 located on the separator SPR and a second dummy layer UP2 located on the first dummy layer UP1. The first dummy layer UP1 and the middle layer IMP may be formed through the same process and may include the same material. The second dummy layer UP2 and the second electrode EL2 may be formed through the same process and may include the same material. That is, the first dummy layer UP1 and the second dummy layer UP2 may be simultaneously formed when forming the middle layer IML and the second electrode EL2. According to some embodiments, the display panel DP may not include the dummy layer UP.

As illustrated in FIG. 9B, according to some embodiments, the second electrode EL2 may include a first end portion EN1a, and the second dummy layer UP2 may include a second end portion EN2a. The first end portion EN1a may be spaced apart from the separator SPR and be positioned on the pixel definition layer PDL, and the second end portion EN2a may be separated from the first end portion EN1a and be positioned on the side surface SPR_W of the separator SPR. However, in FIG. 9B, the first end portion EN1a is illustrated as being spaced apart at an interval (e.g., a set or predetermined interval) from the side surface SPR_W of the separator SPR, the embodiments of the present disclosure are not limited thereto, and if electrically disconnected from the second end portion EN2a, the first end portion EN1a may also contact the side surface SPR_W of the separator SPR. In addition, even when the first end portion EN1a and the second end portion EN2a are connected without being distinguished from each other, when a portion formed along the side surface SPR_W of the separator SPR is thin so that electrical resistance is high, if the second electrode EL2 is electrically disconnected between adjacent pixels, it can be considered that the second electrode EL2 is partitioned by the separator SPR.

According to some embodiments of the present disclosure, even if there is no separate patterning process for the second electrode EL2 or the intermediate layer IML, by preventing or reduce instances of the second electrode EL2 or the intermediate layer IML being formed on the side SPR_W of the separator SPR or by forming the same thin, it is possible to allow the second electrode EL2 or the middle layer IML to be partitioned for each pixel. In addition, as long as the second electrode EL2 or the middle layer IML can be electrically disconnected between adjacent pixels, the shape of the separator SPR may be changed in various ways, and is not limited to any one embodiment.

FIG. 9C is a cross-sectional view showing region CC of FIG. 8 in more detail. Region CC may be a region in which the driving connection part CD is located. The driving connection part CD may include a first layer L1, a second layer L2, and a third layer L3, which are sequentially stacked in the third direction DR3. For the first to third layers L1, L2, and L3, the description of the above-described emission connection part CE may be equally applied. For example, the driving connection part CD may include a stacked structure of the first layer L1 including titanium, the second layer L2 including aluminum, and the third layer L3 including titanium.

The driving connection part CD is arranged while filling the first hole H1 of the first insulation layer VL1, and may be connected to the drain electrode pattern W2 by the first layer Li. The extension wiring CN may arranged while covering the driving connection part CD. Referring to FIG. 9C, the second insulation layer VL2 may be arranged while covering the first insulation layer VL1, the driving connection part CD, and the extension wiring CN.

Meanwhile, in FIG. 9C, the upper surface of the first insulation layer VL1 on a lower side of the first layer L1 is illustrated as having a flat plane without a step, but the embodiments of the present disclosure are not limited thereto, and a portion of the upper surface of the first insulation layer VL1 may not be flat but may have a step around where the first hole H1 is located.

Even when a step is formed in the first insulation layer VL1 by the first hole H1, a portion in which the step is formed does not overlap the light emitting portion EP (see FIG. 8), and thus, does not affect emission properties, and reflected light by external light provided through a light emitting portion is not generated, so that the display device according to some embodiments having the arrangement feature of the first hole H1 may exhibit relatively excellent display quality.

Meanwhile, referring to FIG. 8 and the like, the first hole H1 and the driving connection part CD may not overlap the light emitting layer EML. In addition, the first hole H1 and the driving connection part CD may not overlap the light emitting opening OP-PDL and the first electrode EL1 exposed in the light emitting opening OP-PDL. Because the first hole H1 and the driving connection part CD do not overlap the light emitting opening OP-PDL and the light emitting layer EML, the display device according to some embodiments may exhibit an effect in which display quality degradation caused by external light is relatively reduced.

In the display device DD according to some embodiments as illustrated in FIG. 8, the display panel DP may include an encapsulation layer ECL located on the display element layer DPL. The encapsulation layer ECL may cover the light emitting element LD and may cover the separator SPR. The encapsulation layer ECL may include a first inorganic layer IL1, an organic layer OL, and a second inorganic layer IL2, which are sequentially stacked. However, the embodiments of the present disclosure are not limited thereto, and the encapsulation layer ECL may further include a plurality of inorganic layers and a plurality of organic layers. In addition, the encapsulation layer ECL may be a glass substrate.

The first and second inorganic layers IL1 and IL2 may protect the light emitting element LD from external moisture and oxygen, and the organic layer OL may protect the light emitting element LD from foreign substances such as particles remaining in a process of forming the first inorganic layer IL1. The first and second inorganic layers IL1 and IL2 may include a silicon nitride layer, a silicon oxynitride layer, a silicon oxide layer, a titanium oxide layer, an aluminum oxide layer, or the like. The organic layer OL may include an acrylic organic layer, and the type of material of the organic layer OL is not limited to any one embodiment.

The display device DD may include a sensing layer ISL located on the display panel DP. The sensing layer ISL may sense an external input. According to some embodiments, the sensing layer ISL may be formed on the encapsulation layer ECL through a continuous process. At this time, the sensing layer ISL may be expressed as being directly located on the encapsulation layer ECL. Being directly located may mean that there is no component located between the sensing layer ISL and the encapsulation layer ECL. That is, a separate adhesive member may not be located between the sensing layer ISL and the encapsulation layer ECL. However, this is merely an example, and in the display device DD according to some embodiments of the present disclosure, the sensing layer ISL may be separately formed and then coupled to the display panel DP through an adhesive member, and is not limited to any one embodiment.

The sensing layer ISL may include a plurality of conductive layers and a plurality of insulation layers. The plurality of conductive layers may include a first sensing conductive layer MTL1 and a second sensing conductive layer MTL2, and the plurality of insulation layers may include first to third sensing insulation layers 71, 72, and 73. However, this is merely an example, and the number of conductive layers and the number of insulation layers are not limited to any one embodiment.

Each of the first to third sensing insulation layers 71, 72, and 73 may have a single-layered structure, or may have a multi-layered structure in which layers are stacked along the third direction DR3. The first to third sensing insulation layers 71, 72, and 73 may include an inorganic film. The inorganic film may include at least one of an aluminum oxide, a titanium oxide, a silicon oxide, a silicon nitride, a silicon oxynitride, a zirconium oxide, or a hafnium oxide. The first to third sensing insulation layers 71, 72, and 73 may include an organic film. The organic film may include at least one of an acrylic resin, a methacrylic resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The first sensing conductive layer MTL1 may be located between the first sensing insulation layer 71 and the second sensing insulation layer 72, and the second sensing conductive layer MTL2 may be located between the second sensing insulation layer 72 and the third sensing insulation layer 73. A portion of the second sensing conductive layer MTL2 may be connected to the first sensing conductive layer MTL1 through a contact hole CNT formed on the second sensing insulation layer 72. Each of the first sensing conductive layer MTL1 and the second sensing conductive layer MTL2 may have a single-layered structure, or may have a multi-layered structure in which layers are stacked along the third direction DR3.

A sensing conductive layer of a single-layered structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), indium zinc tin oxide (IZTO), or the like. Alternatively, the transparent conductive layer may include a conductive polymer such as PEDOT, a metal nanowire, graphene, or the like.

A sensing conductive layer of a multi-layered structure may include metal layers. The metal layers may have, for example, a three-layered structure of titanium (Ti)/aluminum (Al)/titanium (Ti). Alternatively, a conductive layer of a multi-layered structure may include at least one metal layer and at least one transparent conductive layer.

The first sensing conductive layer MTL1 and the second sensing conductive layer MTL2 may constitute a sensor configured to sense an external input in the sensing layer ISL. The sensor may be driven in a capacitive manner, and may be driven in any one of a mutual-cap capacitive manner or a self-cap capacitive manner. However, this is merely an example, and the sensor may also be driven in a resistive film method, an ultrasonic manner, or an infrared manner in addition to the capacitive manner, and is not limited to any one embodiment.

Each of the first sensing conductive layer MTL1 and the second sensing conductive layer MTL2 may include a transparent conductive oxide, or may have a metal mesh shape formed of an opaque conductive material. The first sensing conductive layer MTL1 and the second sensing conductive layer MTL2 may have various materials and various shapes as long as the visible recognition of an image displayed by the display panel DP is not degraded, and are not limited to any one embodiment.

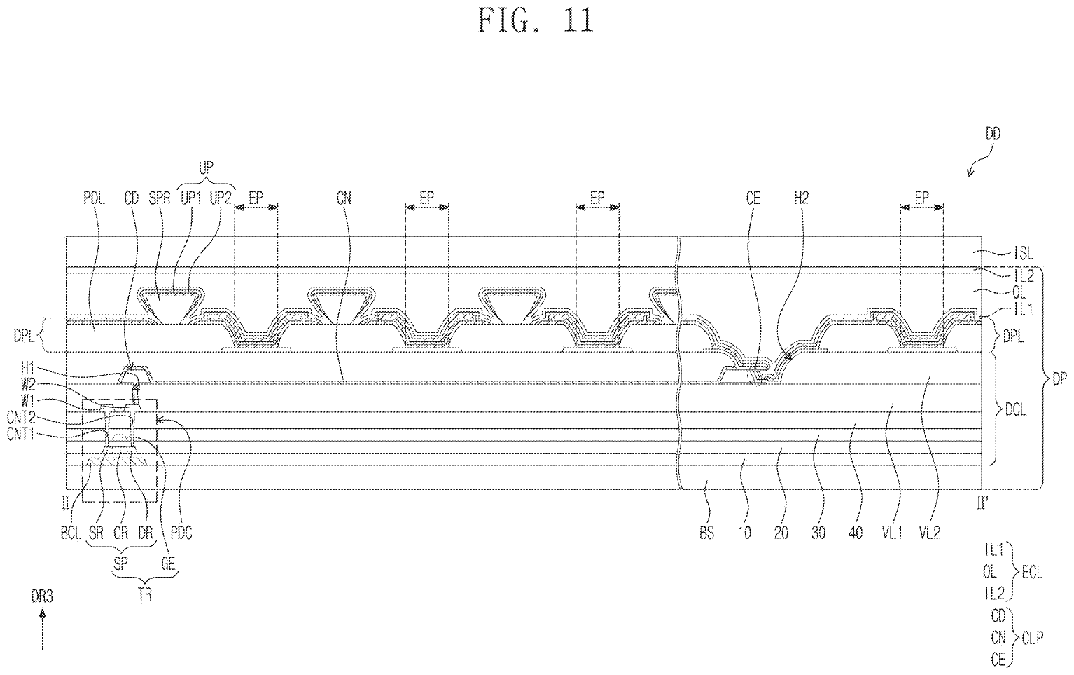

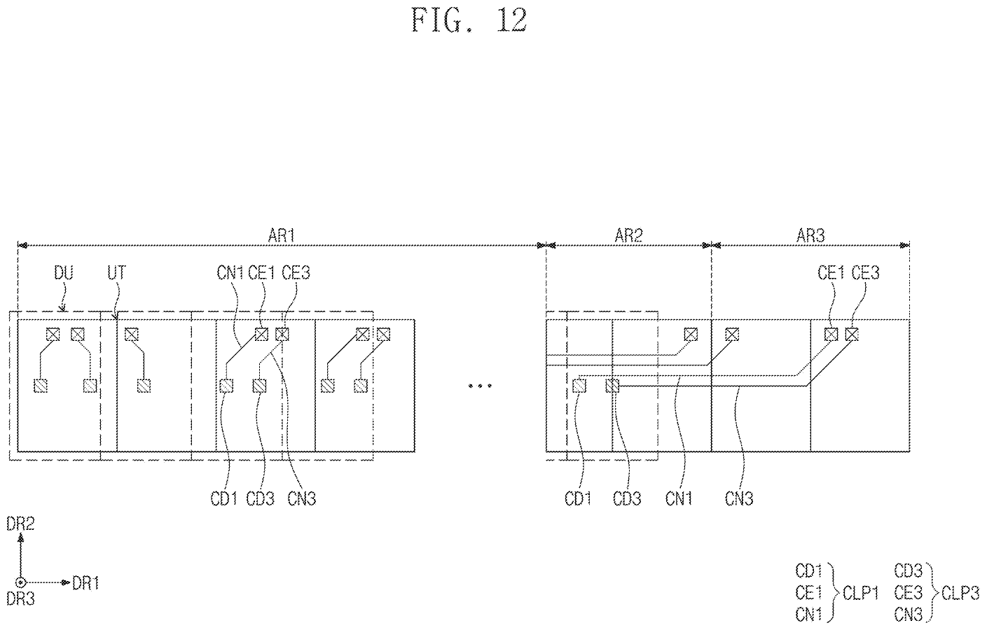

FIG. 10 is a plan view of a partial region of a display panel according to some embodiments of the present disclosure. FIG. 10 may be a plan view of a portion corresponding to region ZZ′ of FIG. 4. FIG. 11 is a cross-sectional view of a partial region of a display device according to some embodiments of the present disclosure. FIG. 11 may be a cross-sectional view of a portion corresponding to the line II-II′ of FIG. 10.

In the description of the display panel and the display device according to some embodiments with reference to FIG. 10 and FIG. 11, the same contents as those described with reference to FIG. 1 to FIG. 9C and the like will not be described again, and instead, differences will be mainly described. FIG. 10 shows a portion of region ZZ′, and FIG. 10 may show portions of a third region AR3 and a second region AR2 of a display region.

Referring to FIG. 10 and FIG. 11, emission connection parts CE1, CE2, and CE3 adjacent to light emitting portions EP1, EP2, and EP3 located in the third region AR3 may be connected to driving connection parts CD1, CD2, and CD3 located in the second region AR2 through extension wirings CN1, CN2, and CN3, respectively. That is, a transistor TR for driving the light emitting portions EP1, EP2, and EP3 located in the third region AR3 and the driving connection parts CD1, CD2, and CD3 connected to the transistor TR may be located in the second region AR2.

Compared to the connection wiring portions located in region YY′ illustrated in FIG. 7A, connection wiring portions of region ZZ′ illustrated in FIG. 10 may be longer. That is, driving connection parts CD1, CD2, and CD3 for driving light emitting portions EP1, EP2, and EP3 located in the first region AR1 (see FIG. 4) are located in a driving unit DU located in the first region AR1 (see FIG. 4), and accordingly, extension wirings CN1, CN2, and CN3 connecting the emission connection parts CE1, CE2, and CE3 and the driving connection parts CD1, CD2, and CD3 may be shorter than extension wirings CN1, CN2, and CN3 connected to emission connection parts CE1, CE2, and CE3 located in the third region AR3, or the second region AR2.

For example, according to some embodiments, a connection line portion CLP in the third region AR3 may be longer than a connection line portion in the first region AR1 (see FIG. 4, and a connection line portion CLP in the second region AR2 may be longer than a connection line portion in the first region AR1 (see FIG. 4). That is, the length of the connection line portion CLP may increase on average from the first region AR1 to the third region AR3.

Referring to FIG. 10, the plurality of driving connection parts CD1, CD2, and CD3 may not overlap the entire light emitting portions EP1, EP2, and EP3 located in the second region AR2 and the third region AR3. In FIG. 10, when viewed on a plane, at least some regions of the driving connection parts CD1, CD2, and CD3 are illustrated as overlapping the separator SPR, but the embodiments of the present disclosure are not limited thereto, and within a range not overlapping the light emitting portions EP1, EP2, and EP3, the driving connection parts CD1, CD2, and CD3 may not overlap the separator SPR.

Referring to FIG. 10 and FIG. 11, the connection line portion CLP connected to a light emitting portion EP located in the third region AR3 extends to the second region AR2, and an extension wiring CN of the connection line portion CLP may overlap a plurality of light emitting portions EP. The extension wiring CN may be formed of a transparent conductive material, and may not affect the quality of light emitted from the light emitting portion EP.

A driving connection part CD electrically connected to a pixel driver PDC in the connection line portion CLP may be located in a first hole H1 defined in a first insulation layer VL1. The plurality of light emitting portions EP may not overlap the first hole H1, and may not overlap the driving connection part CD.

Meanwhile, FIG. 11 illustrates that a capacitor electrode is omitted in the pixel driver PDC, but capacitor electrodes may also be included in the pixel driver PDC illustrated in FIG. 11, and the capacitor electrodes may be spaced apart from the transistor TR in a lower portion of the first insulation layer VL1. The arrangement position of the capacitor electrodes may vary depending on the arrangement of pixel drivers.

FIG. 12 is a view schematically showing the arrangement relationship between light emitting units and driving units connected to the light emitting units in some regions of the display panel. Meanwhile, FIG. 12 illustrates the second region AR2 and the third region AR3 defined on one side of the first region AR1 based on the first region AR1, and illustrates only the connection wiring portions CLP1 and CLP3 connected to emission connection parts CE1 and CE3 located on an upper side, among connections lines in light emitting units and driving units arranged in one row.

In FIG. 12, light emitting units UT are illustrated with solid lines and driving units DU are illustrated with dotted lines. A width of the light emitting units UT in the first direction DR1 may be greater than a width of the driving units DU in the first direction DR1. Therefore, even if the same number of light emitting units UT and driving units DU are located in a display panel DP, the arrangement areas thereof may be different, and accordingly, the light emitting units UT may be located in the first to third regions AR1, AR2, and AR3, and the driving units DU may be located only in the first region AR1 and the second region AR2.

A distance between each of the driving units DU and a light emitting unit UT corresponding to each of the driving units DU may gradually increase from the center of the display panel (e.g., the center of the first region AR1) to an edge of the display panel (e.g., the third region AR3).

In this case, lengths of the first and third connection wiring portions CLP1 and CLP3 may vary. For example, distances between the first and third driving connection parts CD1 and CD3 and the first and third emission connection parts CE1 and CE3 are different in the first region AR1 and the third region AR3, and accordingly, the lengths of the first and third connection wiring portions CLP1 and CLP3 may vary. According to some embodiments, lengths of the second and third extension wirings CN2 and CN3 (see FIG. 10) adjacent to a lower side of one row illustrated in FIG. 12 may also vary.

Thus, as described with reference to FIG. 10 and the like, the first and third extension wirings CN1 and CN3 extending from the first and third emission connection parts CE1 and CE3 located in the third region AR3 may be longer than the first and third extension wirings CN1 and CN3 extending from the first and third emission connection parts CE1 and CE3 located in the first region AR1 and the second region AR2.

In addition, the first and third extension wirings CN1 and CN3 extending from the first and third emission connection parts CE1 and CE3 located in the second region AR2 may be longer than the first and third extension wirings CN1 and CN3 extending from the first and third emission connection parts CE1 and CE3 located in the first region AR1.

In a central portion of the first region AR1, the first and third extension wirings CN1 and CN3 may not extend in the first direction DR1, or portions thereof extending in the first direction DR1 may be small. However, as the distance between a driving unit DU and a light emitting unit UT corresponding to each other increases in the first direction DR1, at least one of the first or third extension wirings CN1 or CN3 may include a portion extending in the first direction DR1.

A plurality of driving connection parts CD1 and CD3 illustrated in FIG. 12 are located in the driving units DU, and the driving connection parts CD1 and CD3 may overlap the light emitting unit UT, but are characterized by not overlapping light emitting portions.

The display device according to some embodiments may exhibit excellent display quality by including a connection line portion which connects a light emitting portion included in a light emitting unit and a pixel driver including in a driving unit, and preventing the arrangement of a driving connection part located in a first hole defined in a first insulation layer of the connection line portion from overlapping the light emitting portion, thereby removing external light reflection in the light emitting portion due to a step caused by the first hole and/or the driving connection part.

A display device according to some embodiments may exhibit excellent display quality by preventing the position at which a driving connection part is connected to a pixel circuit unit from overlapping a light emitting portion, thereby minimizing a step on a lower side of the light emitting portion.

Although aspects of some embodiments of the present invention have been described with reference to some embodiments of the present invention, it will be understood by those skilled in the art that various modifications and changes in form and details may be made therein without departing from the spirit and scope of the present invention as set forth in the following claims, and their equivalents.

Accordingly, the technical scope of embodiments according to the present invention is not intended to be limited to the contents set forth in the detailed description of the specification, but is intended to be defined by the appended claims, and their equivalents.

What is claimed is:

1. A display device comprising:
a display element layer including a plurality of light emitting portions, and a partition structure separating the light emitting portions; and
a circuit layer including a plurality of transistors, a first insulation layer on the transistors and having a plurality of first holes not overlapping the light emitting portions, a second insulation layer on the first insulation layer and having a plurality of second holes not overlapping the first holes, and a plurality of connection wiring portions electrically connecting the light emitting portions and the transistors, wherein:
each of the light emitting portions includes a light emitting element including a first electrode, a second electrode facing the first electrode, and a light emitting layer between the first electrode and the second electrode; and
each of the connection wiring portions includes:
a driving connection part electrically connected in correspondence to each of the transistors, and located in each of the first holes;
an emission connection part electrically connected to the light emitting element, and having one side exposed in each of the second holes; and
an extension wiring for connecting the emission connection part and the driving connection part.

2. The display device of claim 1, wherein the driving connection part in each of the first holes does not overlap the light emitting portions.

3. The display device of claim 1, wherein the first holes do not overlap the light emitting layer.

4. The display device of claim 1, wherein the first electrode is on the second insulation layer, and an upper surface of the first electrode is exposed in a light emitting opening defined in the partition structure, wherein the first holes do not overlap the first electrode exposed in the light emitting opening.

5. The display device of claim 1, wherein the display device is separated into a display region in which the light emitting portions are located and a peripheral region on an outer periphery of the display device, wherein a connection line portion connected to the light emitting portions adjacent to the peripheral region is longer than a connection line portion connected to the light emitting portions in a center of the display region.

6. The display device of claim 1, wherein the light emitting portions comprise a first light emitting portion, a second light emitting portion, and a third light emitting portion, which are configured to emit light of different wavelength regions from each other, wherein the first light emitting portion to the third light emitting portion constitute one light emitting unit, wherein a plurality of light emitting units each including the first to third light emitting portions are arranged in a first direction or in a second direction crossing the first direction.

7. The display device of claim 6, wherein the circuit layer comprises a first pixel driver electrically connected to the first light emitting portion, a second pixel driver electrically connected to the second light emitting portion, and a third pixel driver electrically connected to the third light emitting portion, wherein the first pixel driver to the third pixel driver constitute one driving unit, wherein a plurality of driving units each including the first pixel driver to the third pixel driver are arranged in the first direction or in the second direction.

8. The display device of claim 7, wherein a width of each of the driving units in the first direction is smaller than a width of each of the light emitting units in the first direction.

9. The display device of claim 1, wherein the extension wiring comprises a transparent conductive metal material.

10. The display device of claim 1, wherein the driving connection part and the emission connection part each comprise a first layer including titanium, a second layer on an upper side of the first layer and including aluminum, and a third layer on an upper side of the second layer and including titanium, wherein all of the first through third layers are sequentially stacked.

11. A display device comprising:
a base layer;
a plurality of transistors on the base layer;
an interlayer insulation layer on the transistors;
a first insulation layer on the interlayer insulation layer, and having a plurality of first holes;
a second insulation layer on the first insulation layer, and having a plurality of second holes not overlapping the first holes;
a display element layer on the second insulation layer, and including a pixel definition layer having light emitting openings and a plurality of light emitting elements in each of the light emitting openings; and
a plurality of connection wiring portions including a driving connection part in each of the first holes and electrically connected to the transistors, an emission connection part exposed from each of the second holes and electrically connected to the light emitting elements, and an extension wiring for connecting the driving connection part and the emission connection part, wherein the first holes do not overlap the light emitting openings.

12. The display device of claim 11, wherein each of the light emitting elements comprises a first electrode, a second electrode facing the first electrode, and a light emitting layer between the first electrode and the second electrode, wherein the second electrode includes one end separated from a portion overlapping a second hole from among the second holes.

13. The display device of claim 12, wherein the separated one end of the second electrode is electrically connected to the emission connection part in each of the second holes.

14. The display device of claim 13, wherein a contact hole is defined in the interlayer insulation layer, and an electrode pattern in the contact hole is further included, wherein each of the transistors is connected to the driving connection part through the electrode pattern.

15. A display device separated into a display region including a first region, a second region, and a third region, which are arranged in a first direction, and a peripheral region around the display region, the display device comprising:
a plurality of light emitting units in the first region to the third region, and each including a plurality of light emitting portions;
a plurality of driving units in the first region and the second region, and including a plurality of pixel drivers electrically connected to each of the light emitting portions; and
a plurality of connection wiring portions including an emission connection part connected to each of the light emitting portions, a driving connection part connected to each of the pixel drivers, and an extension wiring for connecting a corresponding emission connection part and the driving connection part, wherein the driving connection part does not overlap the light emitting portions.

16. The display device of claim 15, wherein:
the driving connection part electrically connected to the light emitting portions in the first region is in the first region; and
the driving connection part electrically connected to the light emitting portions in the third region is in the second region.

17. The display device of claim 15, wherein the extension wiring for connecting the emission connection part connected to the light emitting portions in the third region and the driving connection part electrically connected to the emission connection part is longer than the extension wiring for connecting the emission connection part connected to the light emitting portions in the first region and the driving connection part electrically connected to the emission connection part.

18. The display device of claim 15, wherein an extension wiring included in each of the connection wiring portions connected to the light emitting portions in the third region overlaps a plurality of light emitting portions.

19. The display device of claim 15, wherein a width of each of the light emitting units in the first direction is larger than a width of each of the driving units in the first direction.

20. The display device of claim 15, wherein the pixel drivers each comprise a transistor and an electrode pattern on the transistor and connected to the transistor, wherein the transistor includes:
a semiconductor pattern including a source region, a drain region, and a channel region between the source region and the drain region; and
a gate electrode on an upper side of the semiconductor pattern,
wherein the driving connection part is electrically connected to the drain region through the electrode pattern.
